(19) United States
(12) Patent Application Publication
(10) Pub. No.: US 2017/0025370 A1
(43) Pub. Date: Jan. 26, 2017

(54) CHIP SCALE SENSING CHIP PACKAGE AND A MANUFACTURING METHOD THEREOF

(71) Applicant: XINTEC INC., Taoyuan City (TW)

(72) Inventors: Yin-Chen CHEN, New Taipei City (TW); Jan-Lian LIAO, Taoyuan City (TW); Ming-Chieh HUANG, Kaohsiung City (TW); Jyh-Wei CHEN, New Taipei City (TW); Hsi-Chien LIN, Zhubei City (TW)

(21) Appl. No.: 15/209,723

(22) Filed: Jul. 13, 2016

Related U.S. Application Data
(60) Provisional application No. 62/196,133, filed on Jul. 23, 2015.

(51) Int. Cl. H01L 23/00; H01L 21/768; H01L 23/31; H01L 21/683; H01L 21/78

(52) U.S. Cl. CPC H01L 24/06; H01L 21/6835; H01L 24/45; H01L 24/43; H01L 24/05; H01L 24/03; H01L 21/78; H01L 23/3171; H01L 21/76802; H01L 21/76877; H01L 2224/0231; H01L 2224/04042; H01L 2224/0401; H01L 2224/0233; H01L 2224/0605; H01L 24/29

(57) ABSTRACT

This present invention provides a method of manufacturing a chip scale sensing chip package, comprising the steps of: providing a sensing device wafer having a first top surface and a first bottom surface opposite to each other, whereby the sensing device wafer comprises a plurality of chip areas, and each of the chip areas comprising a sensing device and a plurality of conductive pads adjacent to the sensing chip nearby the first top surface; providing a cap wafer having a second top surface and a second bottom surface opposite to each other, and bonding the second surface of the cap wafer to the first top surface of the sensing device wafer by sandwiching a first adhesive layer therebetween; providing a temporary carrier substrate, and bonding the temporary carrier substrate to the second top surface of the cap wafer by sandwiching a second adhesive layer therebetween; forming a wiring layer connecting to each of the conductive pads on the first bottom surface of the sensing device wafer; providing a first protective layer on the wiring layer; removing the temporary carrier substrate and the second adhesive layer; forming a second protective layer on the second top surface; removing the first protective layer; scribing the chip areas to generate a plurality of individual chip scale sensing chip package; and removing the second protective layer.

This application claims the benefit of U.S. provisional application No. 62/196,133, filed on Jul. 23, 2015, and the entirety of which is incorporated by reference herein.

### BACKGROUND OF THE INVENTION

Field of the Invention

The present invention relates to a sensing chip package and in particular relates to a chip scale sensing chip package and a manufacturing method thereof.

Description of the Related Art

A conventional chip package having sensing function is easily contaminated or damaged during the manufacturing processes which results in decreasing both the yield and liability of conventional chip package having sensing functions. In order to meet the tendency of size-miniaturization of electronic components, it is an import subject to minimize the thickness of a substrate for carrying a semiconductor chip to be packaged. The circuit is formed on a thin chip layer during the manufacturing process of a package substrate. However, if a thin substrate for carrying a semiconductor chip to be packaged is utilized, the yield will be reduced owing to the thin substrate is bended or damaged during the package process.

Accordingly, this invention provides a novel chip scale sensing chip package and a manufacturing method thereof, wherein a temporary carrier substrate was introduced to make a thinner cap wafer cap on a sensing chip wafer, and the temporary carrier substrate can be peeled off after subsequent wafer-level package processes, then a chip scale sensing chip with a thinner cap having higher sensitivity is obtained.

### SUMMARY OF THE INVENTION

A feature of this invention provides a method of manufacturing a chip scale sensing chip package, comprising the steps of: providing a sensing device wafer having a first top surface and a first bottom surface opposite to each other, whereby the sensing device wafer comprises a plurality of chip areas, and each of the chip areas comprises a sensing chip and a plurality of conductive pads adjacent to the sensing device nearby the first top surface; providing a cap wafer having a second top surface and a second bottom surface opposite to each other, and bonding the second bottom surface of the cap wafer to the first top surface of the sensing device wafer by sandwiching a first adhesive layer therebetween; providing a temporary carrier substrate, and bonding the temporary carrier substrate to the second top surface of the cap wafer by sandwiching a second adhesive layer therebetween; forming a wiring layer connecting to each of the conductive pads on the first bottom surface of the sensing device wafer; providing a first protective layer on the wiring layer; removing the temporary carrier substrate and the second adhesive layer; forming a second protective layer on the second top surface; removing the first protective layer; scribing the chip areas to generate a plurality of individual chip scale sensing chip packages; and removing the second protective layer.

Another feature of this invention provides a method of manufacturing a chip scale sensing chip package as mentioned above, whereby the method of manufacturing the wiring layer comprises the steps of: thinning the first bottom surface of the sensing device wafer; forming a plurality of first through holes on the thinned first bottom surface, wherein each of the first through holes exposes one of the conductive pads, and the cross-sectional area of each first through hole decreases with the distance from the thinned first bottom surface; forming a dielectric layer overlaid the thinned first bottom surface and the first through holes and the conductive pads; removing part of the dielectric layer on the bottom of each first through hole, part of conductive pads, part of the first top surface and part of the cap wafer to form a plurality of second through holes, whereby each of the second through holes has two side-walls respectively exposing one of the conductive pads; forming a re-distribution layer on the dielectric layer, and electrically connecting to each conductive pad through each second through hole; forming a passivation layer on the re-distribution layer, whereby the passivation layer has a plurality of third through holes exposing the re-distribution layer; and forming a conductive structure in each third through holes and electrically connecting to the re-distribution layer.

Another feature of this invention provides a method of manufacturing a chip scale sensing chip package as mentioned above, whereby the method of manufacturing the wiring layer comprises the steps of: thinning the first bottom surface of the sensing device wafer; forming a plurality of fourth through holes on the thinned first bottom surface, wherein each of the fourth through holes exposes one of the conductive pads; forming a dielectric layer overlaid the thinned first bottom surface and the fourth through holes and the conductive pads; removing part or all of the dielectric layer on the bottom of each fourth through hole to form a plurality of fifth through holes exposing one of the conductive pads, whereby each of the fifth through holes connects with each of the fourth through holes; forming a re-distribution layer on the dielectric layer, and electrically connecting to each conductive pad through each fifth through hole; forming a passivation layer on the re-distribution layer, whereby the passivation layer has a plurality of sixth through holes exposing the re-distribution layer; and forming a conductive structure in each sixth through holes and electrically connecting to the re-distribution layer.

Another feature of this invention provides a method of manufacturing a chip scale sensing chip package as mentioned above, whereby the method of manufacturing the wiring layer comprises the steps of: thinning the first bottom surface of the sensing device wafer; forming a plurality of seventh through holes on the thinned first bottom surface, wherein each of the seventh through holes exposes one of the conductive pads; forming a dielectric layer overlaid the thinned first bottom surface, the seventh through holes and the conductive pads; removing part or all of the dielectric layer on the bottom of each seventh through hole to form a plurality of eighth through holes exposing the conductive pads, whereby each of the eighth through holes connects with each of the fourth through holes; forming a re-distribution layer on the dielectric layer, and electrically connecting to each conductive pad through each eighth through hole; removing part of the re-distribution layer, part of the dielectric layer, part of the sensing device wafer, part of the dielectric layer and part of the first adhesive layer locating on the boundary of two adjacent chip areas to form a trench; forming a passivation layer on the re-distribution layer and the trench, whereby the passivation layer has a plurality of ninth through holes exposing the re-distribution layer; and forming a conductive structure in each ninth through holes and electrically connecting to the re-distribution layer.

Another feature of this invention provides another method of manufacturing a chip scale sensing chip package, comprising the steps of: providing a sensing device wafer having a first top surface and a first bottom surface opposite to each other, whereby the sensing device wafer comprises a plurality of chip areas, and each of the chip areas comprises a sensing device and a plurality of conductive pads adjacent to the sensing device nearby the first top surface; providing a stacking layer comprising a cap wafer, a temporary carrier layer and a second adhesive layer sandwiched therebetween, whereby the cap wafer has a second top surface and a second bottom surface opposite to each other, and a dam is formed on the second bottom surface; bonding the dam formed on the stacking layer to the first top surface by a first adhesive layer; forming a wiring layer connecting to each of the conductive pads on the first bottom surface of the sensing device wafer; providing a first protective layer on the wiring layer; removing the temporary carrier substrate and the second adhesive layer; forming a second protective layer on the second top surface; removing the first protective layer; scribing the chip areas to generate a plurality of individual chip scale sensing chip packages; and removing the second protective layer.

Another feature of this invention provides a method of manufacturing a chip scale sensing chip package as mentioned above, whereby the method of manufacturing the wiring layer comprises the steps of: thinning the first bottom surface of the sensing device wafer; forming a plurality of first through holes on the thinned first bottom surface, wherein each of the first through holes exposes one of the conductive pads, and the cross-sectional area of each first through hole decreases with the distance from the first bottom surface; forming a dielectric layer overlaid the thinned first bottom surface and the first through holes and the conductive pads; removing part of the dielectric layer on the bottom of each first through holes, part of conductive pads, part of the first top surface and part of the cap wafer to form a plurality of second through holes, whereby each of the second through holes has two side-walls respectively expose one of the conductive pads; forming a re-distribution layer on the dielectric layer, and electrically connecting to each conductive pad through each second through hole; forming a passivation layer on the re-distribution layer, whereby the passivation layer has a plurality of third through holes exposing the re-distribution layer; and forming a conductive structure in each third through hole and electrically connecting to the re-distribution layer.

Another feature of this invention provides a method of manufacturing a chip scale sensing chip package as mentioned above, whereby the method of manufacturing the wiring layer comprises the steps of: thinning the first bottom surface of the sensing device wafer; forming a plurality of fourth through holes on the thinned first bottom surface, wherein each of the fourth through holes exposes one of the conductive pads; forming a dielectric layer overlaid the thinned first bottom surface and the fourth through holes and the conductive pads; removing part or all of the dielectric layer on the bottom of each fourth through hole to form a plurality of fifth through holes exposing one of the conductive pads, whereby each of the fifth through holes interlinking with each of the fourth through holes; forming a re-distribution layer on the dielectric layer, and electrically connecting to each conductive pad through each fifth through hole; and forming a passivation layer on the re-distribution layer, whereby the passivation layer has a plurality of sixth through holes exposing the re-distribution layer; forming a conductive structure in each sixth through hole and electrically connecting to the re-distribution layer.

Another feature of this invention provides a method of manufacturing a chip scale sensing chip package as mentioned above, whereby the method of manufacturing the wiring layer comprises the steps of: thinning the first bottom surface of the sensing device wafer; forming a plurality of seventh through holes on the thinned first bottom surface, wherein each of the seventh through holes exposes one of the conductive pads; forming a dielectric layer overlaid the thinned first bottom surface, the seventh through holes and the conductive pads; removing part or all of the dielectric layer on the bottom of each seventh through hole to form a plurality of eighth through holes exposing the conductive pads, whereby each of the eighth through holes interlinking with each of the fourth through holes; forming a re-distribution layer on the dielectric layer, and electrically connecting to each conductive pad through each eighth through hole; removing part of the re-distribution layer, part of the dielectric layer, part of the sensing device wafer, part of the dielectric layer and part of the first adhesive layer locating on the boundary of two adjacent chip areas to form a trench; forming a passivation layer on the re-distribution layer and the trench, whereby the passivation layer has a plurality of ninth through holes exposing the re-distribution layer; and forming a conductive structure in each ninth through hole and electrically connecting to the re-distribution layer.

Another feature of this invention provides a method of manufacturing a chip scale sensing chip package as mentioned above, wherein the cap wafer is consisted of a material selected from one of the group consisted of silicon, aluminum nitride, glass and ceramics, or combination thereof.

Another feature of this invention provides a method of manufacturing a chip scale sensing chip package as mentioned above, wherein the temporary carrier substrate is consisted of a material comprising glass.

Another feature of this invention provides a method of manufacturing a chip scale sensing chip package as mentioned above, wherein the first adhesive layer is selected from one of the group consisted of photoresist, polyimide (PI) and epoxy, or combination thereof.

Another feature of this invention provides a method of manufacturing a chip scale sensing chip package as mentioned above, wherein the second adhesive layer is consisted of a material comprising tape.

Another feature of this invention provides a method of manufacturing a chip scale sensing chip package as mentioned above, wherein the conductive structure is selected from solder ball, solder bump or conductive pillar.

Another feature of this invention provides a method of manufacturing a chip scale sensing chip package as mentioned above, wherein the first protective layer is consisted of a material selected from one of the group consisted of tape, glass, aluminum nitride and sapphire, or combination thereof.

Another feature of this invention provides a method of manufacturing a chip scale sensing chip package as mentioned above, wherein the second protective layer is consisted of a material comprising a photo-sensitive glue.

Another feature of this invention provides a method of manufacturing a chip scale sensing chip package as mentioned above, wherein the photo-sensitive glue is a UV glue.

Another feature of this invention provides a method of manufacturing a chip scale sensing chip package as mentioned above, further a step of cleaning the second top surface of the cap wafer before forming the second protective on the second top surface.

Another feature of this invention provides a method of manufacturing a chip scale sensing chip package as mentioned above, wherein the second bottom surface of the cap wafer further comprises a plurality of dams.

Another feature of this invention provides a chip scale sensing chip package, comprising: a chip scale sensing chip, having a first top surface and a first bottom surface opposite to each other, and a first sidewall and a second sidewall connecting to the opposite edges of the first top surface and the first bottom surface, whereby the surface area of the first top surface is greater than that of the first bottom surface, comprising: a sensing device and a plurality of conductive pads nearby the sensing device adjacent to the first top surface, and the first sidewall and the second sidewall respectively exposing one of the edge of the conductive pads; a dielectric layer formed on the first bottom surface and the first, second sidewalls; a re-distribution layer formed on the dielectric layer to respectively interconnect each conductive pad and each conductive structure; a passivation layer overlay the re-distribution layer, and the passivation layer having a plurality of third through holes exposing the re-distribution layer; and a plurality of conductive structures formed in the third through holes, and each conductive structure electrically connecting to the re-distribution layer; and a cap layer capped on the first top surface of the chip scale sensing chip, whereby the surface area of the cap layer is greater than that of the first top surface.

Another feature of this invention provides a chip scale sensing chip package as mentioned above, further comprising a first adhesive layer sandwiched between the cap layer and the first top surface of the chip scale sensing chip.

Another feature of this invention provides a chip scale sensing chip package as mentioned above, further comprising a dam sandwiched between the cap layer and the first adhesive layer.

Another feature of this invention provides a chip scale sensing chip package as mentioned above, wherein the cap layer is consisted of a material selected from one of the group consisted of silicon, aluminum nitride, glass and ceramics, or combination thereof.

Another feature of this invention provides a chip scale sensing chip package as mentioned above, wherein the first adhesive layer is selected from one of the group consisted of photoresist, polyimide (PI) and epoxy, or combination thereof.

Another feature of this invention provides a chip scale sensing chip package as mentioned above, wherein the conductive structure is selected from solder ball, solder bump or conductive pillar.

Another feature of this invention provides another chip scale sensing chip package, comprising: a chip scale sensing chip, having a first top surface and a first bottom surface opposite to each other, comprising: a sensing device and a plurality of conductive pads nearby the sensing device adjacent to the first top surface; a plurality of fourth through holes formed on the first bottom surface, whereby each fourth through hole has a bottom wall exposing one of the conductive pads and a sidewall surrounding the bottom wall; a dielectric layer formed on the first bottom surface and the sidewall of each fourth through hole; a re-distribution layer formed on the dielectric layer to electrically connect each conductive pad through the bottom wall of each fourth through hole; a passivation layer overlay the re-distribution layer, and the passivation layer having a plurality of sixth through holes exposing the re-distribution layer; and a plurality of conductive structures formed in the sixth through holes, and each conductive structure electrically connecting to the re-distribution layer; and a cap layer capped on the first top surface of the chip scale sensing chip.

Another feature of this invention provides a chip scale sensing chip package as mentioned above, further comprising a first adhesive layer sandwiched between the cap layer and the first top surface of the chip scale sensing chip.

Another feature of this invention provides a chip scale sensing chip package as mentioned above, further comprising a dam sandwiched between the cap layer and the first adhesive layer.

Another feature of this invention provides a chip scale sensing chip package as mentioned above, whereby the dielectric layer is formed on the first bottom surface, the bottom wall and the sidewall of each fourth through hole of the chip scale sensing chip, and the bottom wall further comprises a fifth through hole exposing one of the conductive pads, and the re-distribution layer electrically connect to each conductive pad through each fifth through hole.

Another feature of this invention provides a chip scale sensing chip package as mentioned above, wherein the cap layer is consisted of a material selected from one of the group consisted of silicon, aluminum nitride, glass and ceramics, or combination thereof.

Another feature of this invention provides a chip scale sensing chip package as mentioned above, wherein the first adhesive layer is selected from one of the group consisted of photoresist, polyimide (PI) and epoxy, or combination thereof.

Another feature of this invention provides a chip scale sensing chip package as mentioned above, wherein the conductive structure is selected from solder ball, solder bump or conductive pillar.

Another feature of this invention provides another chip scale sensing chip package, comprising: a chip scale sensing chip, having a first top surface and a first bottom surface opposite to each other, comprising: a sensing device and a plurality of conductive pads nearby the sensing device adjacent to the first top surface; a plurality of seventh through holes formed on the first bottom surface, and each seventh through hole having a bottom wall exposing one of the conductive pads and a sidewall surrounding the bottom wall; a trench surrounding the outer of each seventh through hole formed on the first bottom surface; a dielectric layer formed on the first bottom surface and the sidewall of each seventh through hole; a re-distribution layer formed on the dielectric layer to electrically connect each conductive pad through the bottom wall of each fourth through hole; a passivation layer overlay the re-distribution layer and gap-filled into the trench, whereby the passivation layer has a plurality of ninth through holes exposing the re-distribution layer; and a plurality of conductive structures formed in the ninth through holes, and each conductive structure electrically connecting to the re-distribution layer; and a cap layer capped on the first top surface of the chip scale sensing chip.

Another feature of this invention provides a chip scale sensing chip package as mentioned above, further comprising a first adhesive layer between the cap layer and the first top surface of the chip scale sensing chip.

Another feature of this invention provides a chip scale sensing chip package as mentioned above, further comprising a dam between the cap layer and the first adhesive layer.

Another feature of this invention provides a chip scale sensing chip package as mentioned above, whereby the dielectric layer is formed on the first bottom surface, the bottom wall and the sidewall of each seventh through hole of the chip scale sensing chip, and the bottom wall further comprises a eighth through hole exposing one of the conductive pads, and the re-distribution layer electrically connect to each conductive pad through each eighth through hole.

Another feature of this invention provides a chip scale sensing chip package as mentioned above, wherein the cap layer is consisted of a material selected from one of the group consisted of silicon, aluminum nitride, glass and ceramics, or combination thereof.

Another feature of this invention provides a chip scale sensing chip package as mentioned above, wherein the first adhesive layer is selected from one of the group consisted of photoresist, polyimide (PI) and epoxy, or combination thereof.

Another feature of this invention provides a chip scale sensing chip package as mentioned above, wherein the conductive structure is selected from solder ball, solder bump or conductive pillar.

### BRIEF DESCRIPTION OF THE DRAWINGS

FIGS. 1A-1J are cross-sectional views of the exemplary embodiment 1 of a method of manufacturing a chip scale sensing chip package according to this present invention.

FIGS. 2A-2D are cross-sectional views of the exemplary embodiment 2 of a method of manufacturing a chip scale sensing chip package according to this present invention.

FIGS. 3A-3J are cross-sectional views of the exemplary embodiment 3 of a method of manufacturing a chip scale sensing chip package according to this present invention.

FIGS. 4A-4D are cross-sectional views of the exemplary embodiment 4 of a method of manufacturing a chip scale sensing chip package according to this present invention.

FIGS. 5A-5D are cross-sectional views of the exemplary embodiment 5 of a method of manufacturing a chip scale sensing chip package according to this present invention.

FIGS. 6A-6D are cross-sectional views of the exemplary embodiment 6 of a method of manufacturing a chip scale sensing chip package according to this present invention.

FIGS. 7A-7K are cross-sectional views of the exemplary embodiment 7 of a method of manufacturing a chip scale sensing chip package according to this present invention.

FIGS. 8A-8D are cross-sectional views of the exemplary embodiment 8 of a method of manufacturing a chip scale sensing chip package according to this present invention.

FIGS. 9A-9D are cross-sectional views of the exemplary embodiment 9 of a method of manufacturing a chip scale sensing chip package according to this present invention.

FIGS. 10A-10D are cross-sectional views of the exemplary embodiment 10 of a method of manufacturing a chip scale sensing chip package according to this present invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific exemplary embodiments discussed are merely illustrative of specific methods to make and use the embodiments, and do not limit the scope of the disclosure.

### Exemplary Embodiment 1

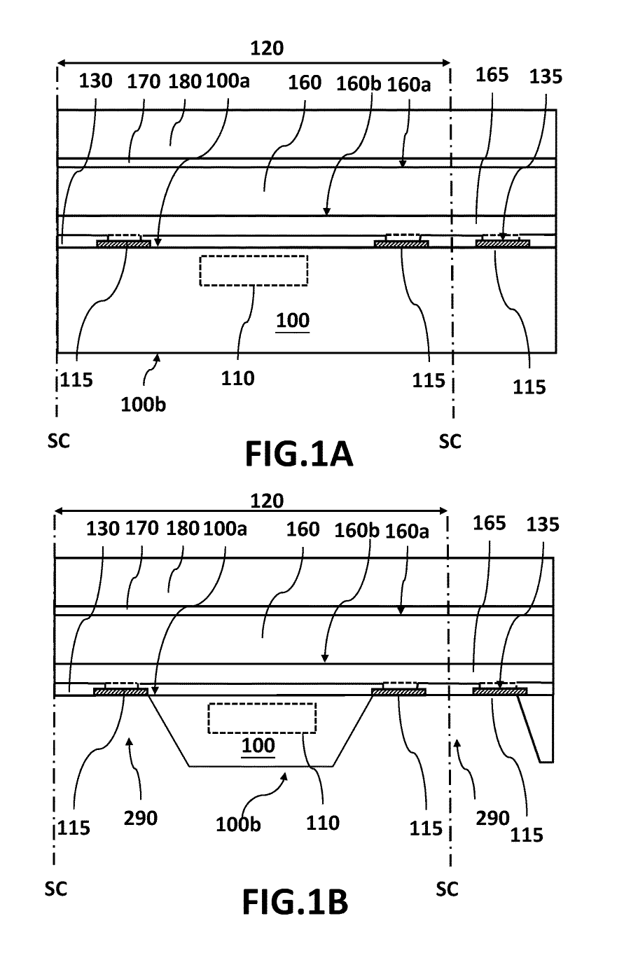

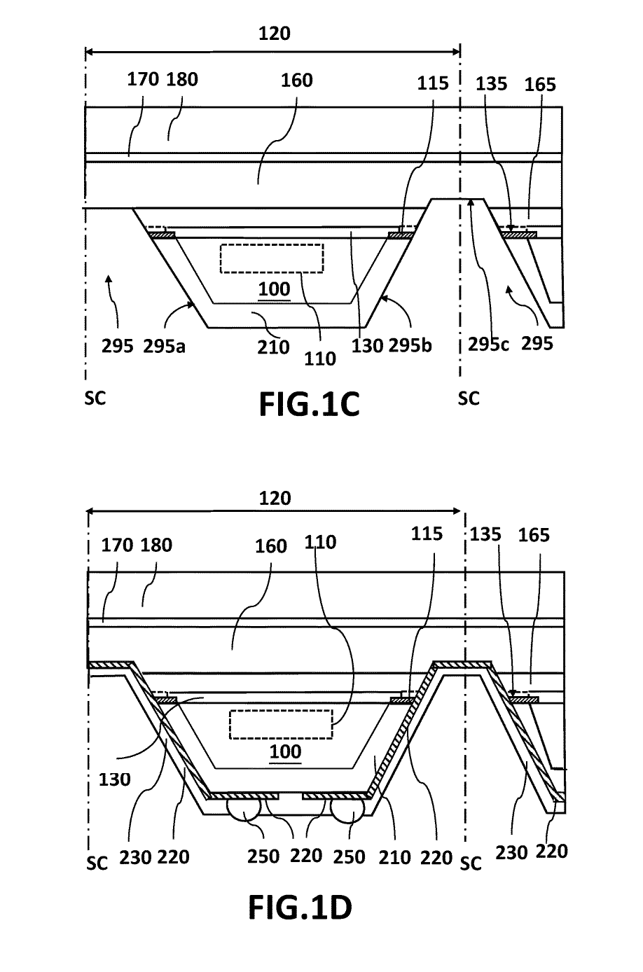

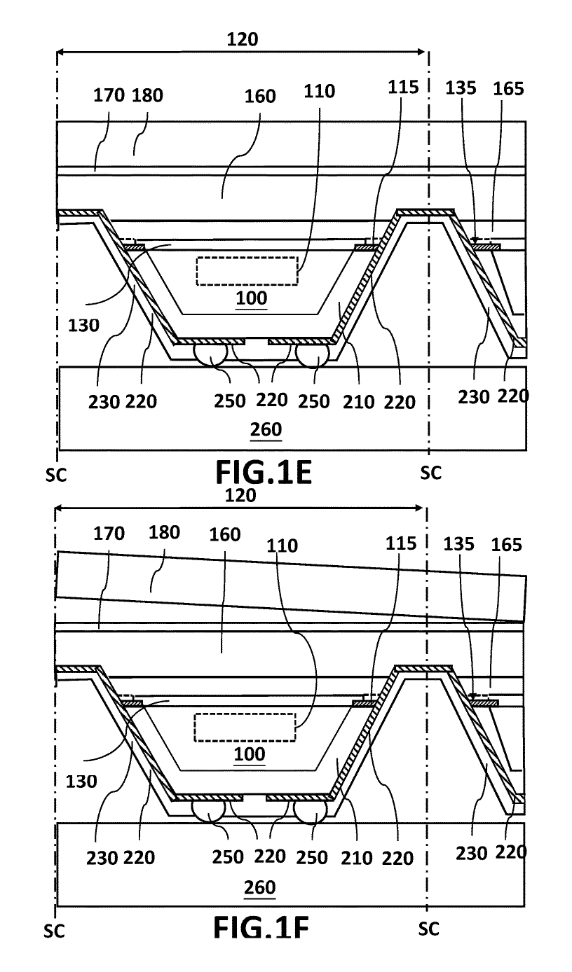

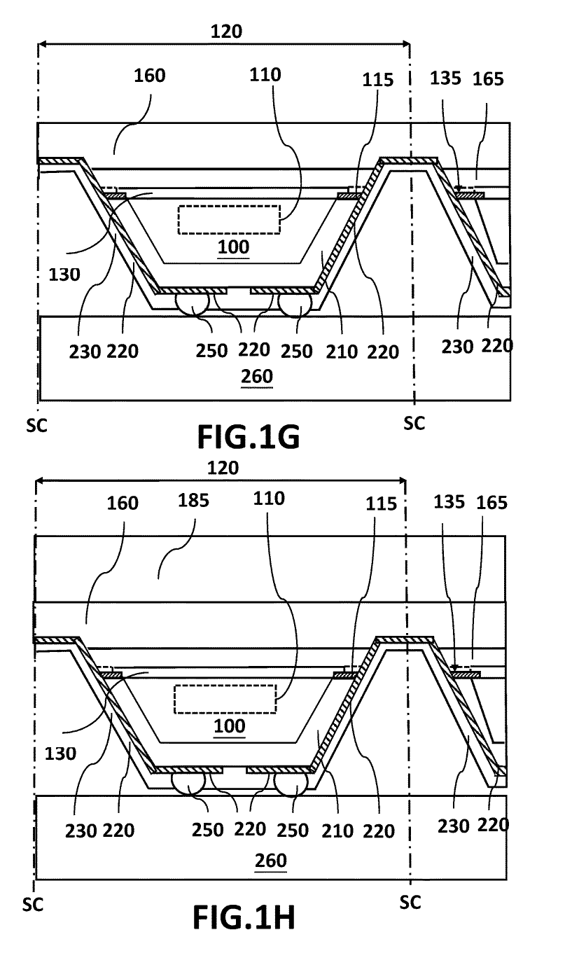

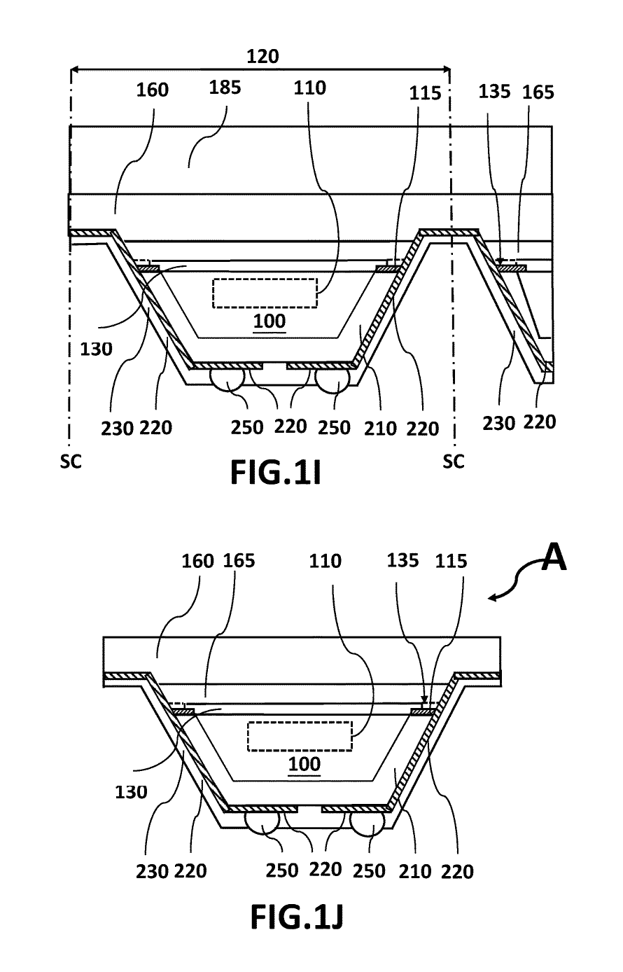

A detailed description of the chip scale sensing chip package and a method of manufacturing the same according to embodiment 1 of this invention is given below with reference to the accompany FIGS. 1A-1J.

First, please refer to FIG. 1A. A sensing device wafer 100 having a first top surface 100a and a first bottom surface 100b opposite to each other is provided, wherein the sensing device wafer 100 comprises a plurality of chip areas 120, and each of the chip areas 120 comprises a sensing device 110 and a plurality of conductive pads 115 formed on an insulating layer 139 and adjacent to the sensing device 110 nearby the first top surface 100a. Moreover, a plurality of opening 135 can be selectively formed to expose the conductive pads 115 if necessary.

Next, a cap wafer 160 with a thickness of 100-200 μm and having a second top surface 160a and a second bottom surface 160b opposite to each other is provided. Then, an adhesive layer 165 selected from one of the group photoresist, polyimide (PI) and epoxy or combination thereof is coated on the second bottom surface 160b, and the cap wafer 160 is bonded to the sensing device wafer 100 by sandwiching the first adhesive layer 165 between the second bottom surface 160b and the insulating layer 130 formed on the sensing device wafer 100. Then, a temporary carrier substrate 180 with a thickness of 400 μm is provided and bonded to the second top surface 160a of the cap wafer 160 by sandwiching a second adhesive layer 170 therebetween. The temporary carrier substrate 180 of this embodiment is consisted of glass, and the second adhesive layer 170 of this invention is consisted of tape.

Next, please refer to FIG. 1B. The first bottom surface 100b of the sensing device wafer 100 is thinned by etching, milling, grinding or polishing to reduce the thickness of the sensing device wafer 100 and generate a thinner sensing device wafer 100 with a thickness of about 75-135 μm. Then, a plurality of first through holes 290 exposing the conductive pads 115 are formed on the first bottom surface 100b by photolithography and subsequent etching processes such as dry etching, wet etching, plasma etching, RIE etching or other suitable process.

Next, please refer to FIG. 1C. A dielectric layer 210 is formed on the first bottom surface 100b of the sensing device wafer 100 and filled into the first through holes 290 by spin-coating, PVD, CVD or other suitable deposition processes. The dielectric layer 210 of this embodiment can be selected from a material consisted of epoxy, inorganic material such as silicon oxide, silicon nitride, silicon oxynitride, metal oxide or combination thereof, organic polymer such as polyimide resin, benzocyclobutadiene, poly-p-xylene, naphthalene polymer, fluorocarbon compound, acrylate, solder mask or other suitable insulating materials.

Next, a notching process is applied to remove part of the dielectric layer 210 on the bottom of each first through hole 290, the insulating layer 130 adjacent to the first through holes 290, part of the conductive pads 115, part of the first adhesive layer 165 and part of the cap wafer 160 to form a plurality of second through holes 295. Each of the second through holes 295 has a bottom wall 295c, a first side-wall 295a and a second side-wall 295b, wherein the first side-wall 295a and the second side-wall 295b respectively expose the edges of each conductive pad 115.

Next, please refer to FIG. 1D. A patterned re-distribution layer 220 is formed on the dielectric layer 210, the first side-wall 295a, second side-wall 295b and the bottom wall 295c by deposition such as spin-coating, PVD, CVD or other suitable process and subsequent photolithography and etching processes. The re-distribution layer 220 can be selected from one of the group consisted of aluminum, copper, gold, platinum, nickel, tin, or combination thereof, conductive polymers, conductive ceramics such as ITO or IZO, or other suitable conductive materials.

Next, a passivation layer 230 is formed to overlay the re-distribution layer 220 by passivation and subsequent photolithography and etching processes. The passivation layer 230 has a plurality of third through holes (not shown) exposing the re-distribution layer 220, and a plurality of conductive structures 250 such as solder balls, solder bumps or conductive pillar are formed in the third through holes (not shown) by electroplating, screen printing or other suitable processes to electrically connect to the re-distribution layer 220. The passivation layer 230 of this embodiment can be selected from a material consisted of epoxy, inorganic material such as silicon oxide, silicon nitride, silicon oxynitride, metal oxide or combination thereof, organic polymer such as polyimide resin, benzocyclobutadiene, poly-p-xylene, naphthalene polymer, fluorocarbon compound, acrylate, solder mask or other suitable insulating materials. The conductive structures 250 can be selected from one of the group consisted of tin, lead, copper, gold, nickel, or combination thereof, or other suitable conductive materials.

Next, please refer to FIG. 1E. A first protective layer 260 is provided to overlay the conductive structures 250. The first protective layer 260 is consisted of a material selected from one of the group consisted of tape, glass, aluminum nitride and sapphire, or combination thereof. The first protective layer 260 of this embodiment is a tape.

Next, please refer to FIG. 1F and FIG. 1G. The temporary carrier substrate 180 and the second adhesive layer 170 are peeled off, then the second top surface 160a of the cap wafer 160 is cleaned to remove residual glue or dust thereon.

Next, please refer to FIG. 1H. A second protective layer 185 is formed on the second top surface 160a of the cap wafer 160. Then, please refer to FIG. 1I. The first protective layer 260 is peeled off. The second protective layer 185 is consisted of a material comprising a photo-sensitive glue, and the second protective layer 185 of this embodiment is a UV glue.

Finally, please refer to FIG. 1J. A scribing process is applied along the scribing channels SC to scribe the passivation layer 230, the re-distribution layer 220, the cap wafer 160 and the second protective layer 185, and a plurality of individual chip scale sensing chip package A are generated after the second protective layer 185 is peeled off by UV exposure.

### Exemplary Embodiment 2

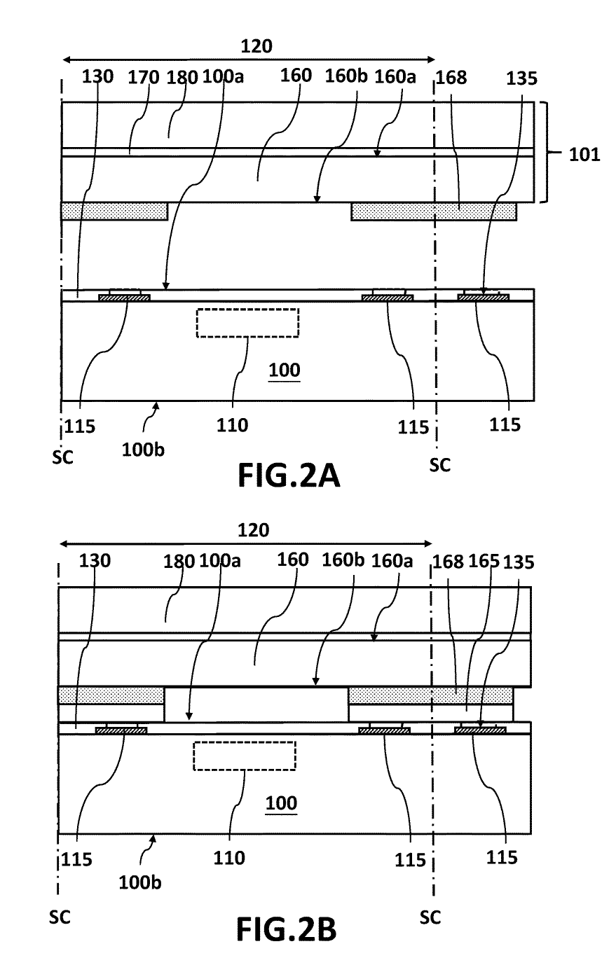

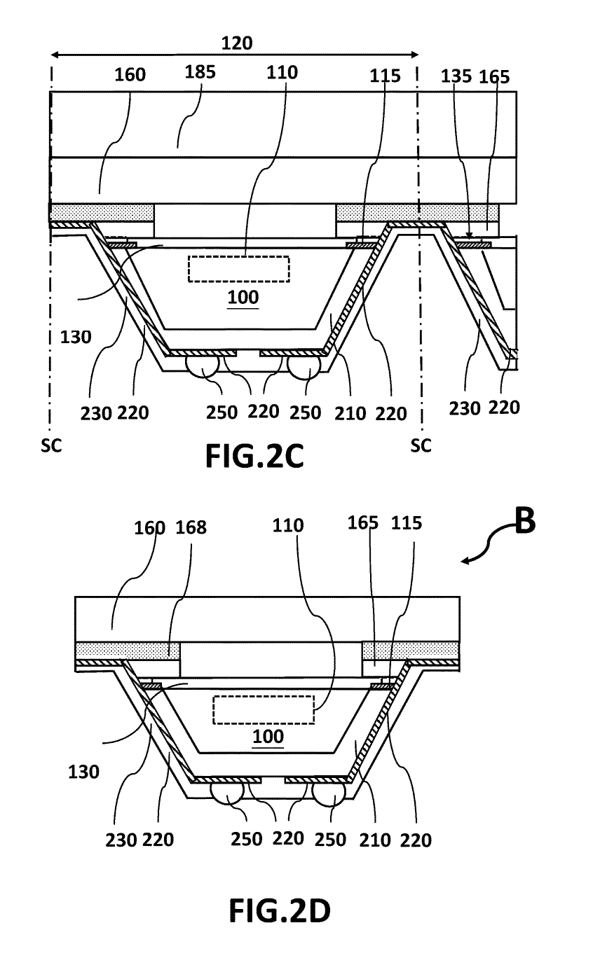

A detailed description of the chip scale sensing chip package and a method of manufacturing the same according to embodiment 2 of this invention is given below with reference to the accompany FIGS. 2A-2D.

First, please refer to FIG. 2A. A sensing device wafer 100 as mentioned in the exemplary embodiment 1 is provided. Next, a stacking layer 101 comprising a cap wafer 160, a second adhesive layer 170 and a temporary carrier substrate 180 is provided. The stacking layer 101 has a second top surface 160a and a second bottom surface 160b opposite to each other, and the temporary carrier substrate 180 is bonded to the second top surface 160a of the cap wafer 160 by sandwiching the second adhesive layer 170 therebetween. Then, a dam 168 is formed on the second bottom surface 160b of the cap wafer 160. The dam 168 of this embodiment is consisted of photoresist.

Next, please refer to FIG. 2B. A first adhesive layer 165 is coated on the dam 168 to make the stacking layer 101 bond to the first top surface 100a of the sensing device wafer 100.

Next, the structure as shown in FIG. 2B is treated with the same processes as shown in FIG. 1B-FIG. 1I to generate the structure as shown in FIG. 2C.

Finally, the structure as shown in FIG. 2C is treated with the same processes as shown in FIG. 1J to generate a plurality of chip scale sensing chip packages B as shown in FIG. 2D.

### Exemplary Embodiment 3

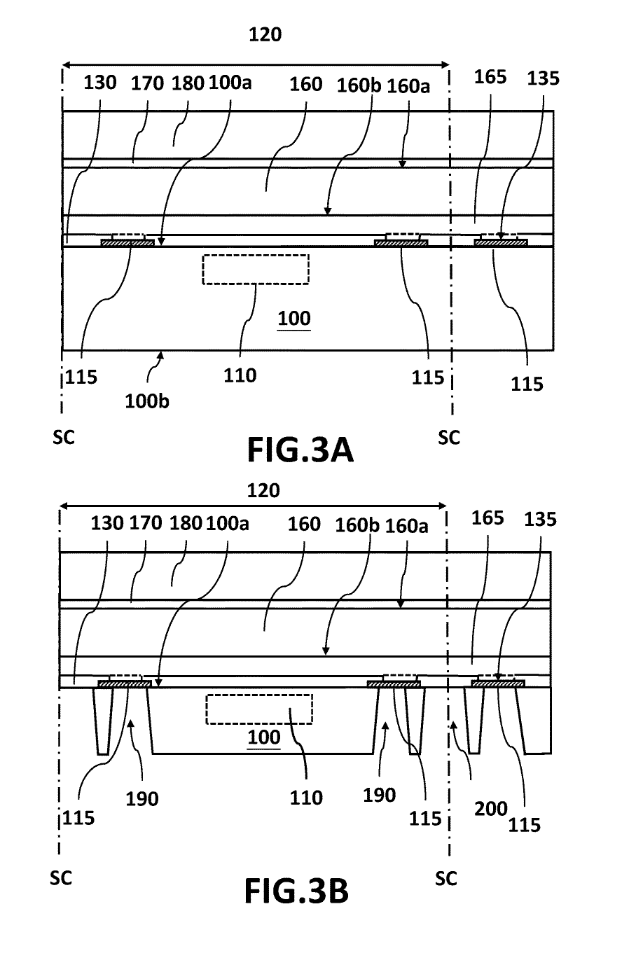

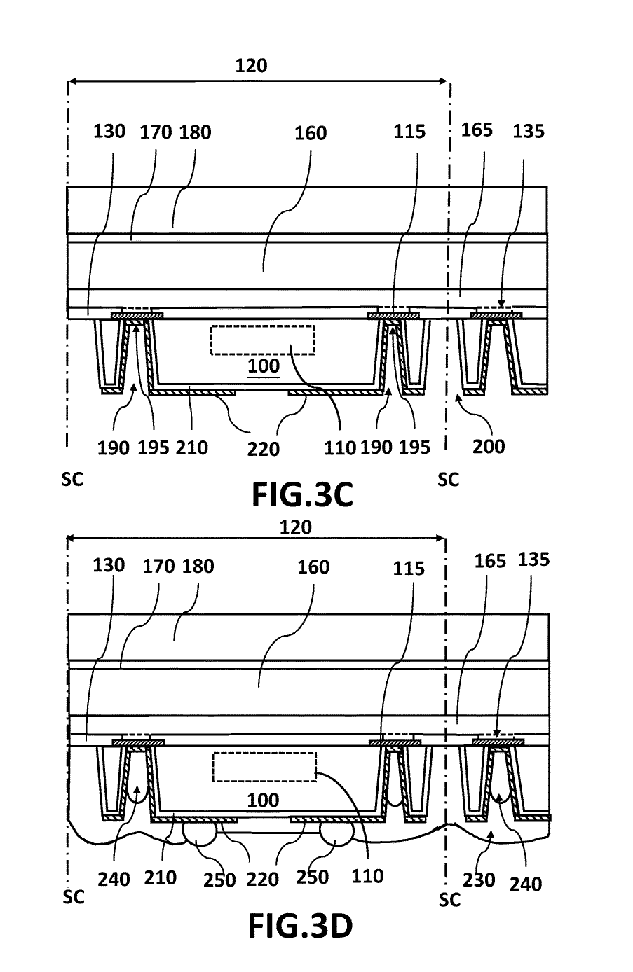

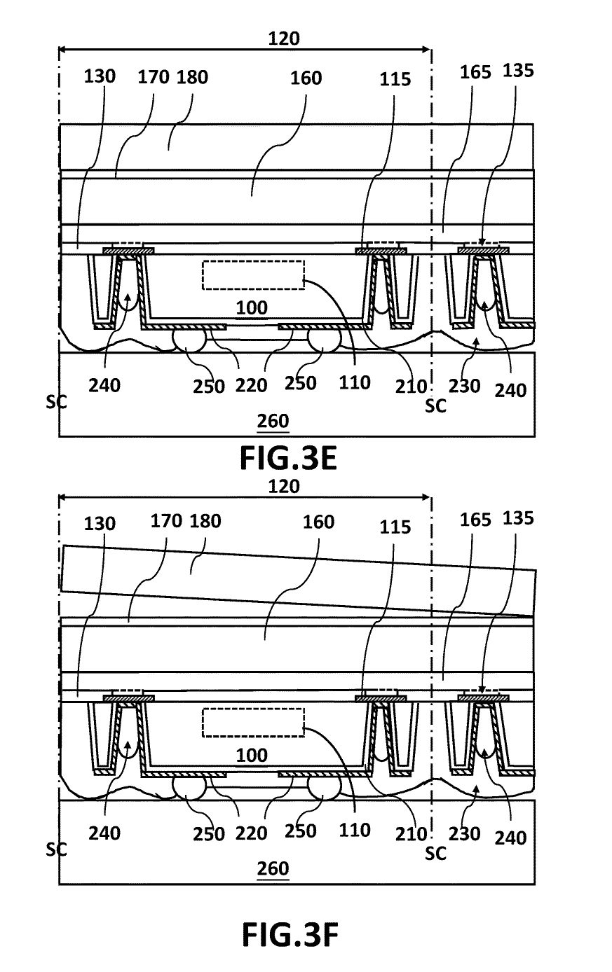

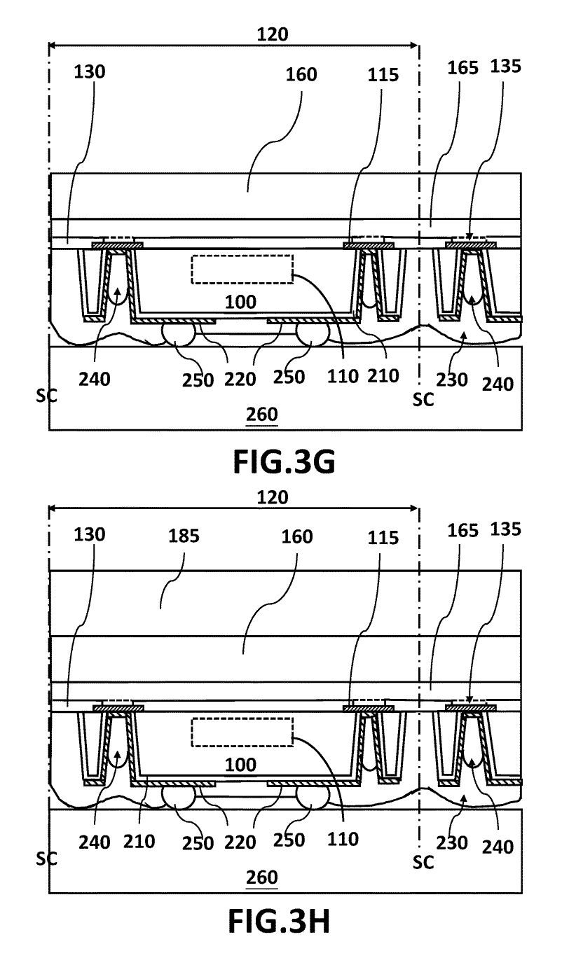

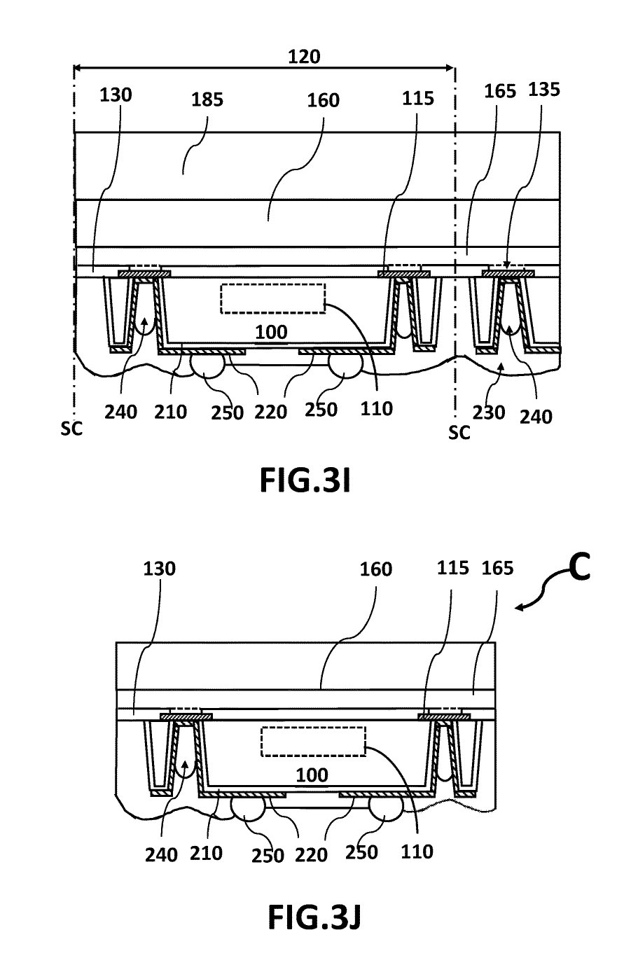

A detailed description of the chip scale sensing chip package and a method of manufacturing the same according to embodiment 3 of this invention is given below with reference to the accompany FIGS. 3A-3J.

First, please refer to FIG. 3A. A sensing device wafer 100 caped with a cap wafer 160 and a temporary carrier substrate 180 as shown in FIG. 1A is provided.

Next, please refer to FIG. 3B. The first bottom surface 100b of the sensing device wafer 100 is thinned by etching, milling, grinding or polishing to reduce the thickness of the sensing device wafer 100 and generate a thinner sensing device wafer 100 with a thickness of about 85-105 μm. Then, a plurality of fourth through holes 290 exposing the conductive pads 115 and a plurality of openings 200 aligned with the scribing channels SC are formed on the first bottom surface 100b by photolithography and subsequent etching processes such as dry etching, wet etching, plasma etching, RIE etching or other suitable process.

Next, please refer to FIG. 3C. A dielectric layer 210 is formed on the first bottom surface 100b of the sensing device wafer 100 and filled into the fourth through holes 190 and openings 200 by spin-coating, PVD, CVD or other suitable deposition processes. The dielectric layer 210 of this embodiment can be selected from a material consisted of epoxy, inorganic material such as silicon oxide, silicon nitride, silicon oxynitride, metal oxide or combination thereof, organic polymer such as polyimide resin, benzocyclobutadiene, poly-p-xylene, naphthalene polymer, fluorocarbon compound, acrylate, solder mask or other suitable insulating materials.

Next, the dielectric layer 210 on the bottom (not shown) of the fourth through holes 190 is removed to form a plurality of fifth through holes 195 exposing the conductive pads 115. Then, a patterned re-distribution layer 220 is formed on the dielectric layer 210 by spin-coating, PVD, CVD or other suitable deposition processes and subsequent photolithography and etching processes. The re-distribution layer 220 comfortably extends onto the sidewalls (not shown) of the fourth through holes 190 and into the fifth through holes 195, but not extends into the openings 200. The re-distribution layer 220 can electrically connect to each conductive pad 115 via each fifth through hole 195. Moreover, the re-distribution layer 220 of other embodiments can be an unsymmetrical pattern. For example, the re-distribution layer 220 within the fourth through hole 190 nearby the outer edge (not shown) of the chip area 120 adjacent to the scribing channels SC does not extend upward to the first bottom surface 100b.

Next, please refer to FIG. 3D. A passivation layer 230 is formed on the second bottom surface 100b and filled into the fourth holes 190 and openings 200 to overlay the re-distribution layer 220 by passivation and subsequent photolithography and etching processes. The passivation layer 230 has a plurality of sixth through holes (not shown) exposing the re-distribution layer 220, and a plurality of conductive structures 250 such as solder balls, solder bumps or conductive pillar are formed in the sixth through holes (not shown) by electroplating, screen printing or other suitable processes to electrically connect to the re-distribution layer 220. The passivation layer 230 of this embodiment can be selected from a material consisted of epoxy, inorganic material such as silicon oxide, silicon nitride, silicon oxynitride, metal oxide or combination thereof, organic polymer such as polyimide resin, benzocyclobutadiene, poly-p-xylene, naphthalene polymer, fluorocarbon compound, acrylate, solder mask or other suitable insulating materials. The conductive structures 250 can be selected from one of the group consisted of tin, lead, copper, gold, nickel, or combination thereof, or other suitable conductive materials.

The passivation layer 230 of this embodiment is just partially filled up with the fourth through holes 190, and a void 240 is formed between the re-distribution layer 220 and the passivation layer 230 of the fourth through holes. In one of the embodiments, the boundary between the void 240 and the passivation 230 is an arc profile. The fourth through holes 190 can also be filled up with the passivation layer 230 in other embodiments of this invention.

Next, please refer to FIG. 3E. A first protective layer 260 is provided to overlay the conductive structures 250. The first protective layer 260 is consisted of a material selected from one of the group consisted of tape, glass, aluminum nitride and sapphire, or combination thereof. The first protective layer 260 of this embodiment is a tape.

Next, please refer to FIG. 3F and FIG. 3G. The temporary carrier substrate 180 and the second adhesive layer 170 are peeled off, then the second top surface 160a of the cap wafer 160 is cleaned to remove residual glue or dust thereon.

Next, please refer to FIG. 3H. A second protective layer 185 is formed on the second top surface 160a of the cap wafer 160. Then, please refer to FIG. 1I. The first protective layer 260 is peeled off. The second protective layer 185 is consisted of a material comprising a photo-sensitive glue, and the second protective layer 185 of this embodiment is a UV glue.

Finally, please refer to FIG. 3J. A scribing process is applied along the scribing channels SC to scribe the passivation layer 230, the re-distribution layer 220, the cap wafer 160 and the second protective layer 185, and a plurality of individual chip scale sensing chip package C are generated after the second protective layer 185 is peeled off by UV exposure.

### Exemplary Embodiment 4

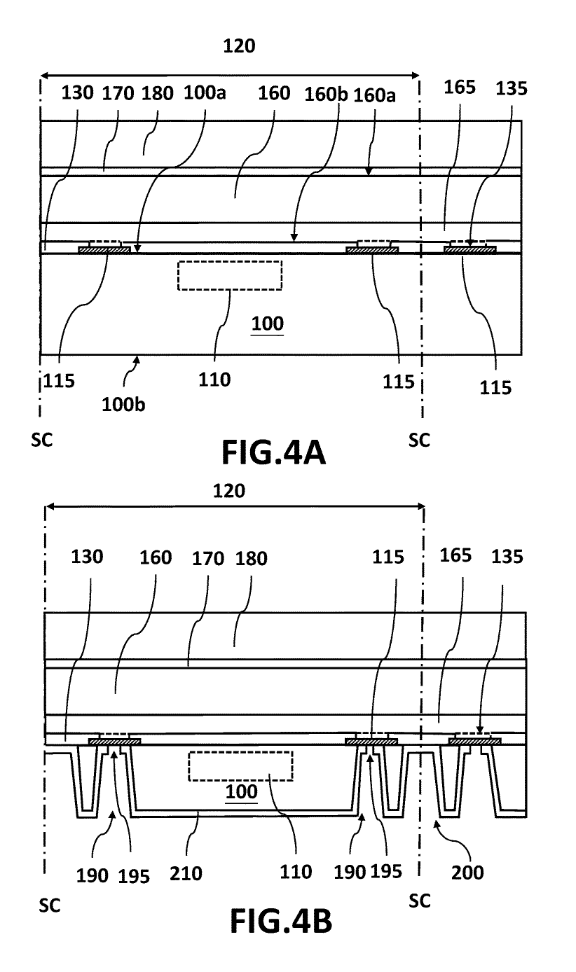

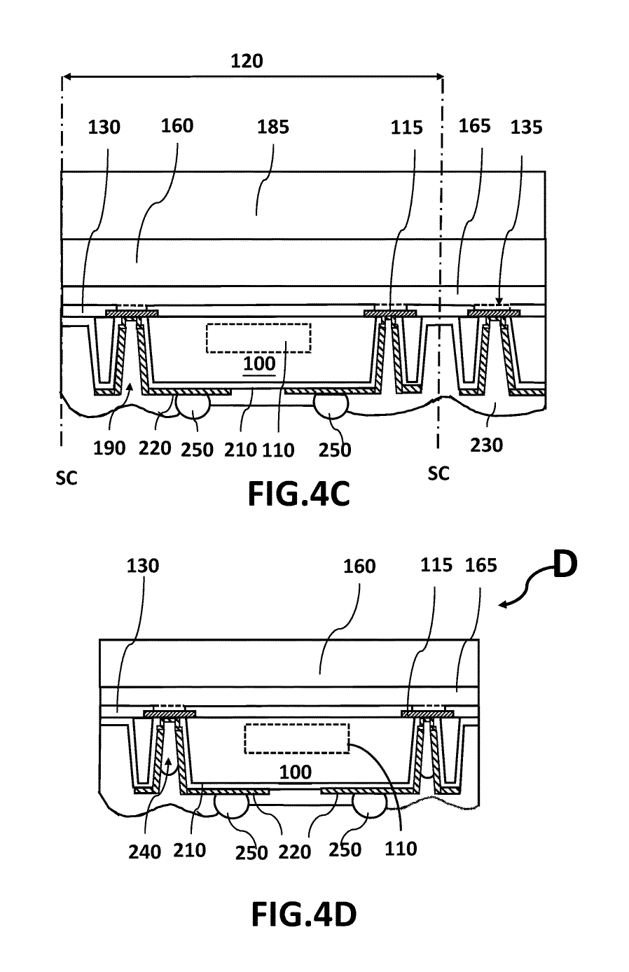

A detailed description of the chip scale sensing chip package and a method of manufacturing the same according to embodiment 4 of this invention is given below with reference to the accompany FIGS. 4A-4D.

First, please refer to FIG. 4A. A sensing device wafer 100 caped with a cap wafer 160 and a temporary carrier substrate 180 as shown in FIG. 1A is provided.

Next, please refer to FIG. 4B. The first bottom surface 100b of the sensing device wafer 100 is treated with the processes as shown in FIG. 3B to formed a plurality of fourth through holes 190 exposing the conductive pads 115 and a plurality of opening 200 aligned with the scribing channels SC. Then, a dielectric layer 210 is formed on the first bottom surface 100b of the sensing device wafer 100 and filled into the fourth through holes 190 and openings 200, and part of the dielectric layer 210 on the bottom (not shown) of the fourth through holes 190 is removed to form a plurality of fifth through holes 195′ exposing the conductive pads 115, whereby each fourth through hole 190 interlinks with each fifth through hole 195 and passes through to each other.

Next, please refer to FIG. 4C. A patterned re-distribution layer 220 is formed on the dielectric layer 210. The re-distribution layer 220 comfortably extends onto the sidewalls (not shown) and the bottom wall (not shown) of the fourth through holes 190 and into the fifth through holes 195′, but not extends into the openings 200. The re-distribution layer 220 can electrically connect to each conductive pad 115 via each fifth through hole 195. Then, a structure as shown in FIG. 4C is generated after treated with the same processes as shown in FIG. 3C-3I.

Finally, please refer to FIG. 4D. The structure as shown in FIG. 4C is treated with the same processes as shown in FIG. 3J to generate a plurality of chip scale sensing chip packages D as shown in FIG. 4D.

### Exemplary Embodiment 5

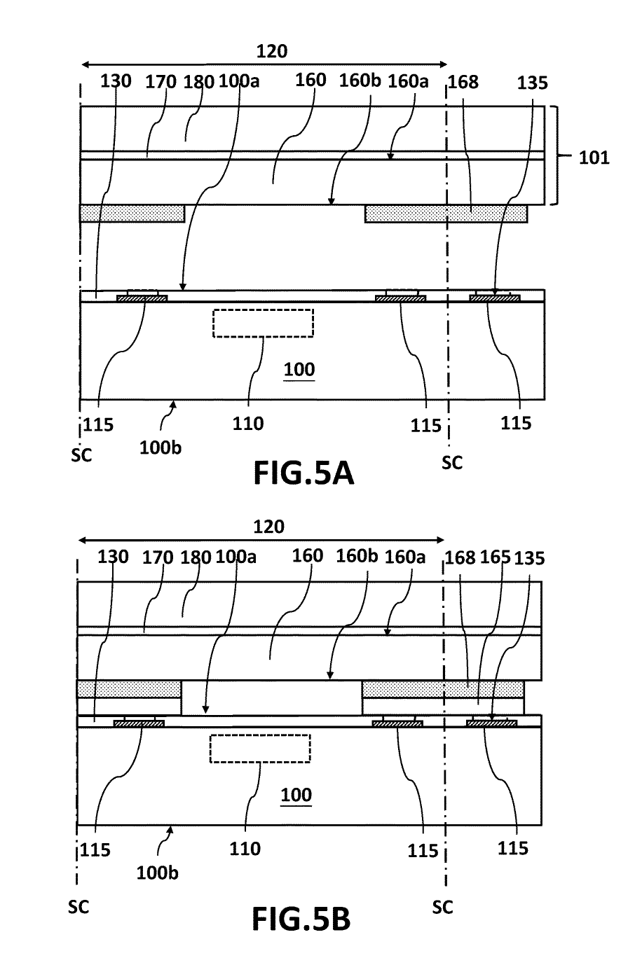

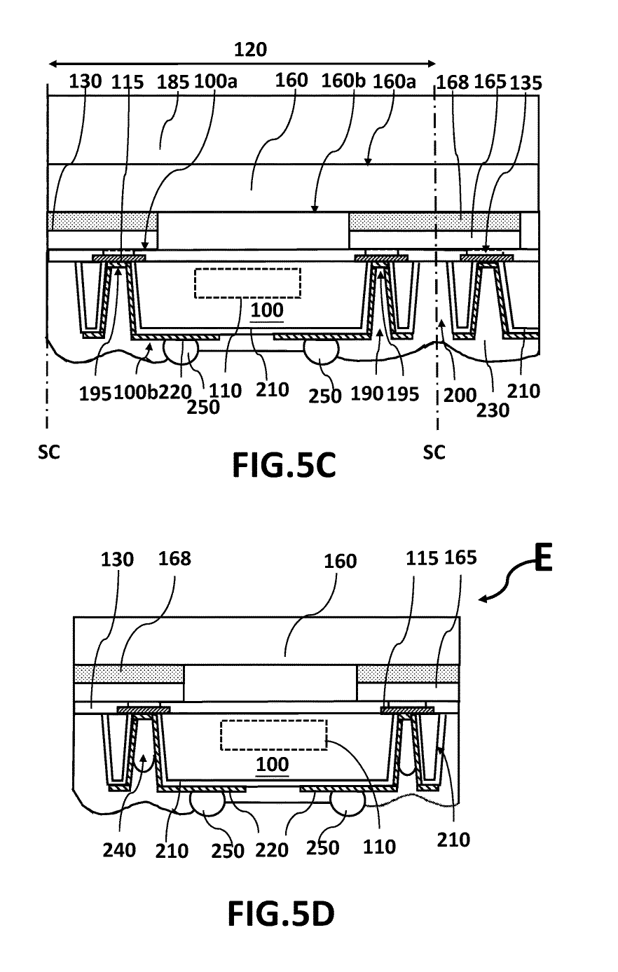

A detailed description of the chip scale sensing chip package and a method of manufacturing the same according to embodiment 5 of this invention is given below with reference to the accompany FIGS. 5A-5D.

First, please refer to FIG. 5A. A sensing device wafer 100 and a stacking layer 101 comprising a cap wafer 160, a second adhesive layer 170 and a temporary carrier substrate 180 as shown in FIG. 2A are provided. Then, a dam 168 is formed on the second bottom surface 160b of the cap wafer 160.

Next, the structure as shown in FIG. 5B is treated with the same processes as shown in FIG. 3B-3I to generate a structure as shown in FIG. 5C.

Finally, please refer to FIG. 5D. The structure as shown in FIG. 5C is treated with the same processes as shown in FIG. 3J to generate a plurality of chip scale sensing chip packages E as shown in FIG. 5D.

### Exemplary Embodiment 6

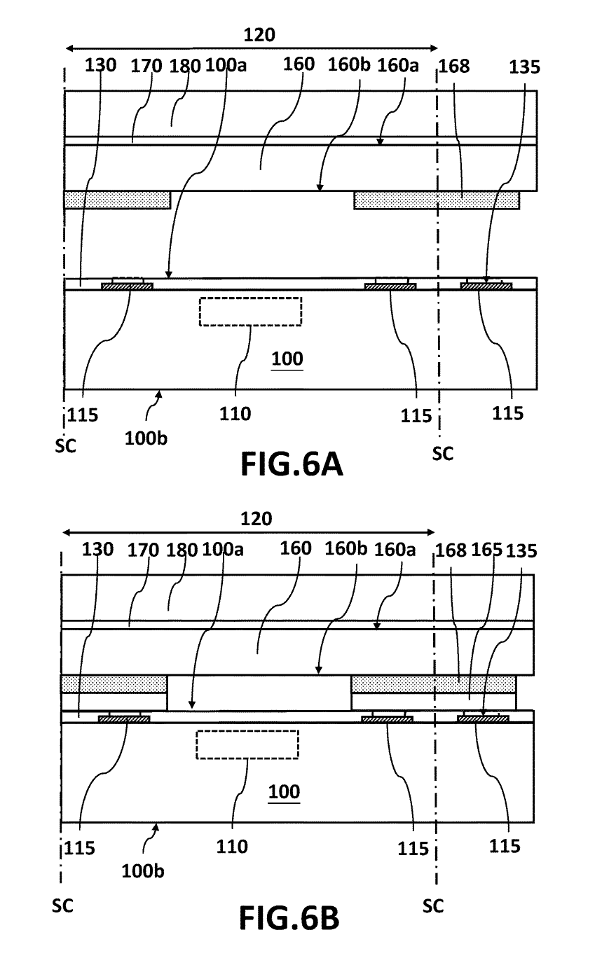

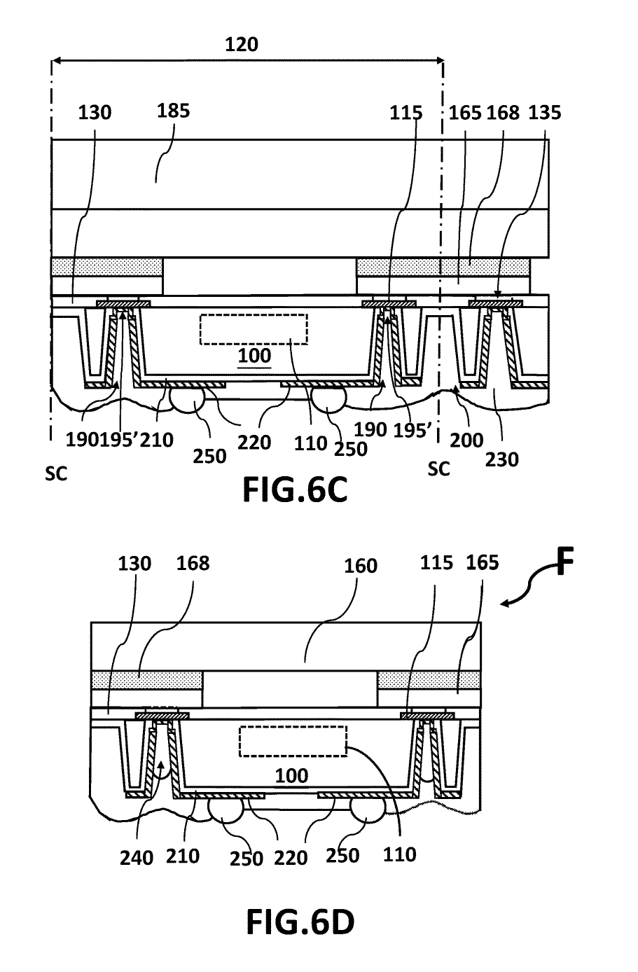

A detailed description of the chip scale sensing chip package and a method of manufacturing the same according to embodiment 6 of this invention is given below with reference to the accompany FIGS. 6A-6D.

First, please refer to FIG. 6A. A sensing device wafer 100 and a stacking layer 101 comprising a cap wafer 160, a second adhesive layer 170 and a temporary carrier substrate 180 as shown in FIG. 2A are provided. Then, a dam 168 is formed on the second bottom surface 160b of the cap wafer 160. Next, please refer to FIG. 6B. A first adhesive layer 165 is coated on the dam 168 to make the stacking layer 101 bond to the first top surface 100a of the sensing device wafer 100.

Next, the structure as shown in FIG. 6B is treated with the same processes as shown in FIG. 4B-FIG. 4C to generate the structure as shown in FIG. 6C.

Finally, the structure as shown in FIG. 6C is treated with the same processes as shown in FIG. 3J to generate a plurality of chip scale sensing chip packages F as shown in FIG. 6D.

### Exemplary Embodiment 7

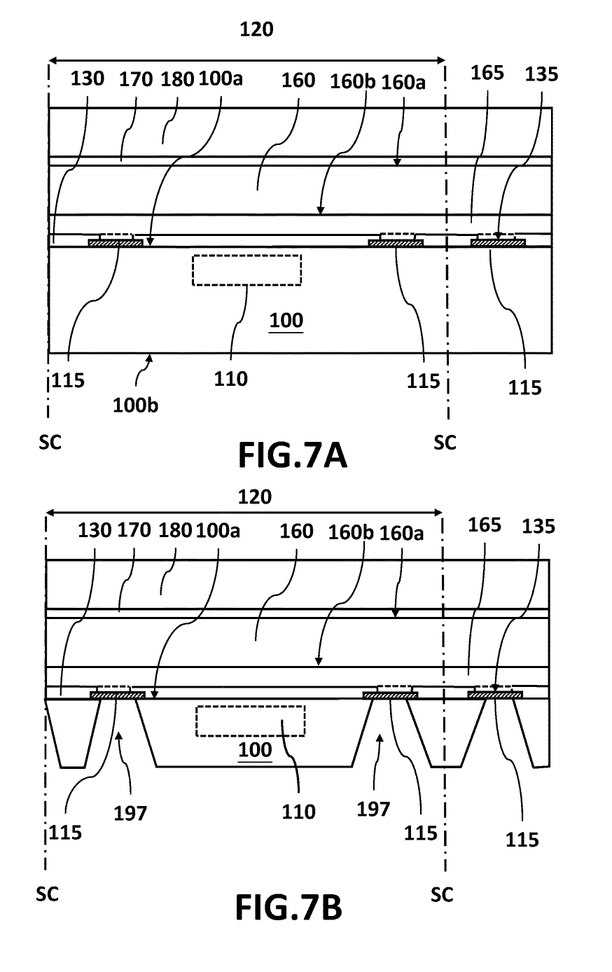

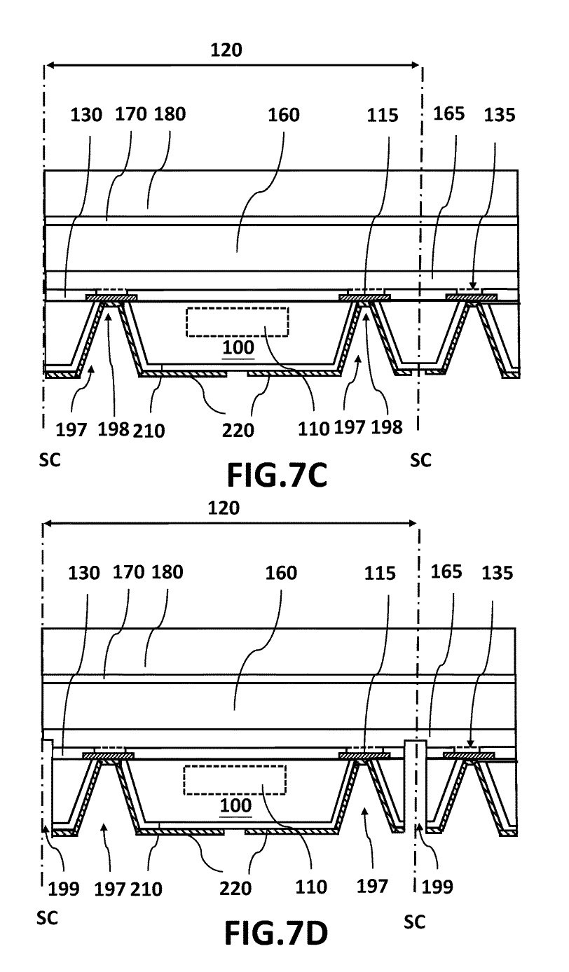

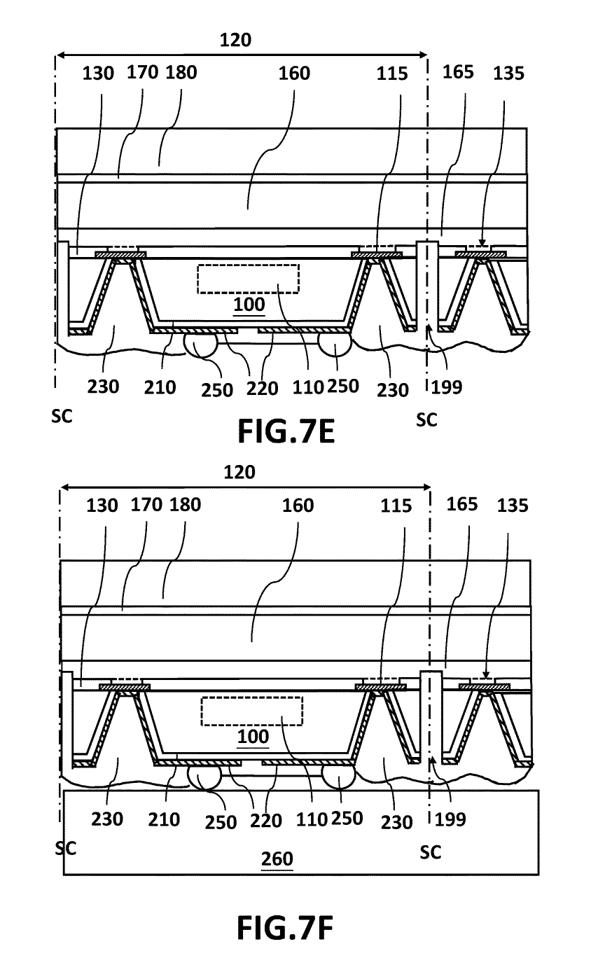

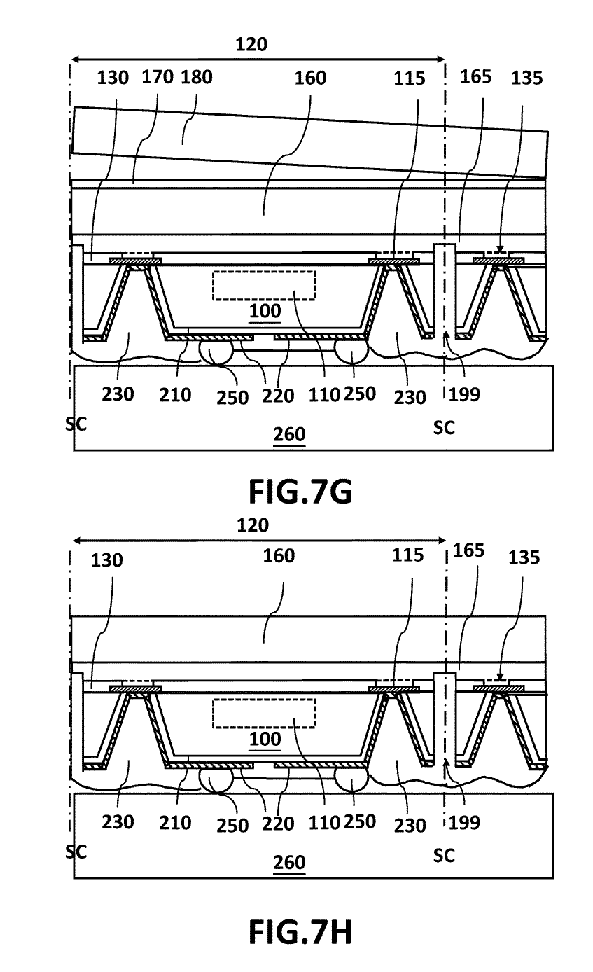

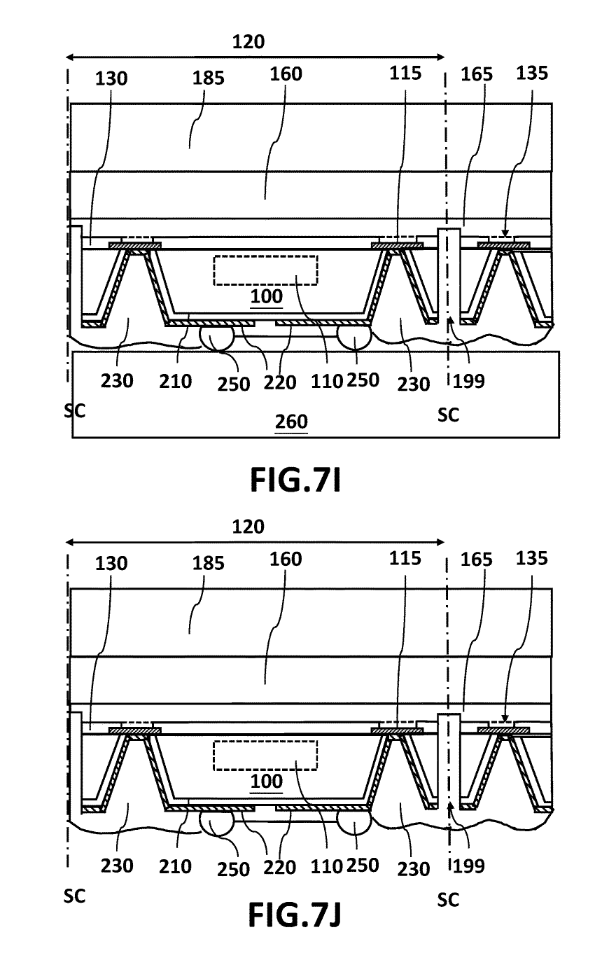

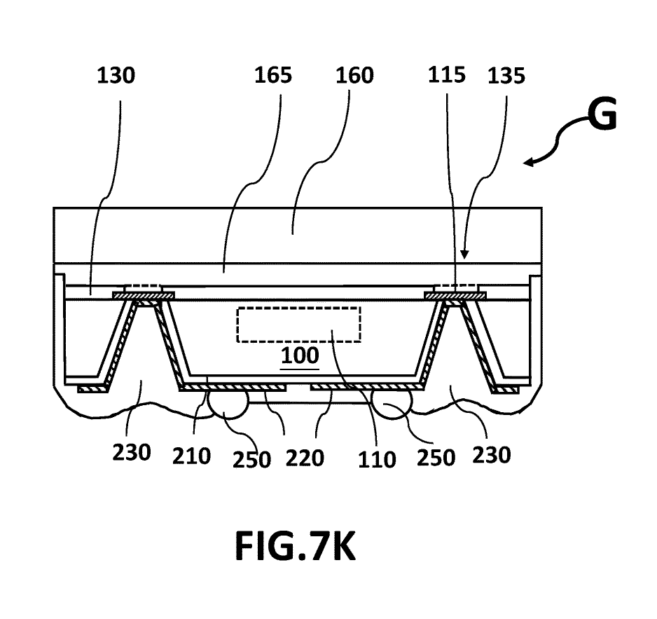

A detailed description of the chip scale sensing chip package and a method of manufacturing the same according to embodiment 7 of this invention is given below with reference to the accompany FIGS. 7A-7K.

First, please refer to FIG. 7A. A sensing device wafer 100 caped with a cap wafer 160 and a temporary carrier substrate 180 as shown in FIG. 1A is provided.

Next, please refer to FIG. 7B. The first bottom surface 100b of the sensing device wafer 100 is thinned by etching, milling, grinding or polishing to reduce the thickness of the sensing device wafer 100 and provide a thinner sensing device wafer 100 with a thickness of about 85-105 μm. Then, a plurality of seventh through holes 197 exposing the conductive pads 115 are formed on the first bottom surface 100b of each chip area 120.

Next, please refer to FIG. 7C. A dielectric layer 210 is formed on the first bottom surface 100b of the sensing device wafer 100 and filled into the seventh through holes 197. Then the dielectric layer 210 on the bottom of the seventh through holes 197 are removed to form a plurality of eighth through holes 198 exposing the conductive pads 115. Then, a patterned re-distribution layer 220 is formed on the dielectric layer 210. The patterned re-distribution layer 220 conformable extends onto the sidewalls (not shown) of the seventh through holes 197 and into the eighth through holes 198 to electrically connect to the exposed conductive pads 115.

Next, please refer to FIG. 7D. Part of the dielectric layer 210, part of the sensing device wafer 100, part of the dielectric layer 130 and part of the first adhesive layer 165 near the scribing channels locating on the boundary of two adjacent chip areas are removed to form a plurality of trench 199 by cleavage or photolithography followed by etching.

Next, please refer to FIG. 7E. A passivation layer 230 is formed on the second bottom surface 100b to overlay the re-distribution layer 220 and filled into the seventh through holes 197 and the trenches 199. The passivation layer 230 has a plurality of ninth through holes (not shown) exposing the re-distribution layer 220, and a plurality of conductive structures 250 such as solder balls, solder bumps or conductive pillar are formed in the ninth through holes (not shown) to electrically connect to the re-distribution layer 220.

Next, please refer to FIG. 7F. A first protective layer 260 is provided to overlay the conductive structures 250. The first protective layer 260 is consisted of a material selected from one of the group consisted of tape, glass, aluminum nitride and sapphire, or combination thereof. The first protective layer 260 of this embodiment is a tape.

Next, please refer to FIG. 7G-7H. The temporary carrier substrate 180 and the second adhesive layer 170 are peeled off, then the second top surface 160a of the cap wafer 160 is cleaned to remove residual glue or dust thereon.

Next, please refer to FIG. 71. A second protective layer 185 is formed on the second top surface 160a of the cap wafer 160. Then, please refer to FIG. 1I. The first protective layer 260 is peeled off. The second protective layer 185 is consisted of a material comprising a photo-sensitive glue, and the second protective layer 185 of this embodiment is a UV glue.

Finally, please refer to FIG. 7K. A scribing process is applied along the scribing channels SC within the trenches to scribe the passivation layer 230, the re-distribution layer 220, the cap wafer 160 and the second protective layer 185, and a plurality of individual chip scale sensing chip package G are generated after the second protective layer 185 is peeled off by UV exposure.

### Exemplary Embodiment 8

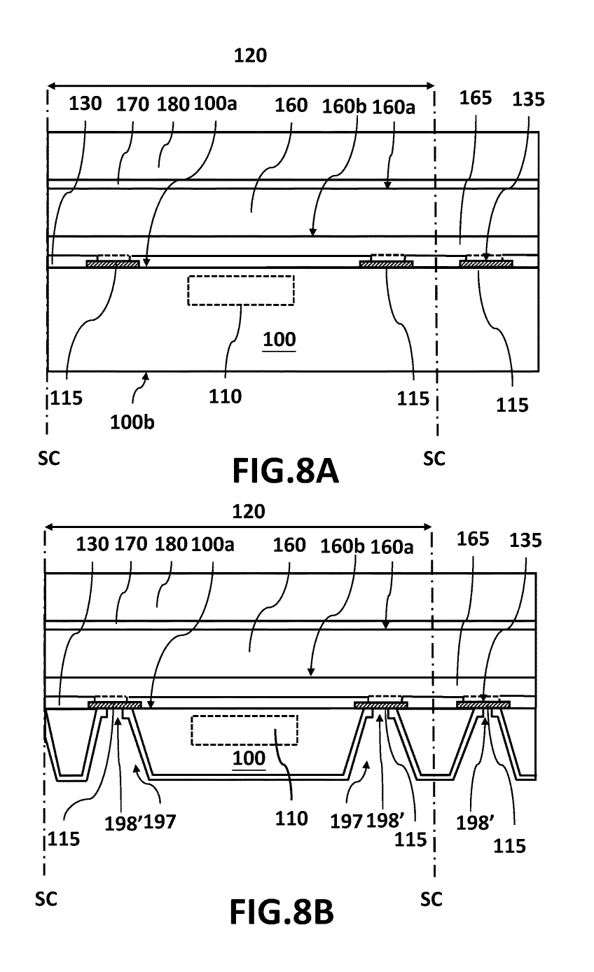

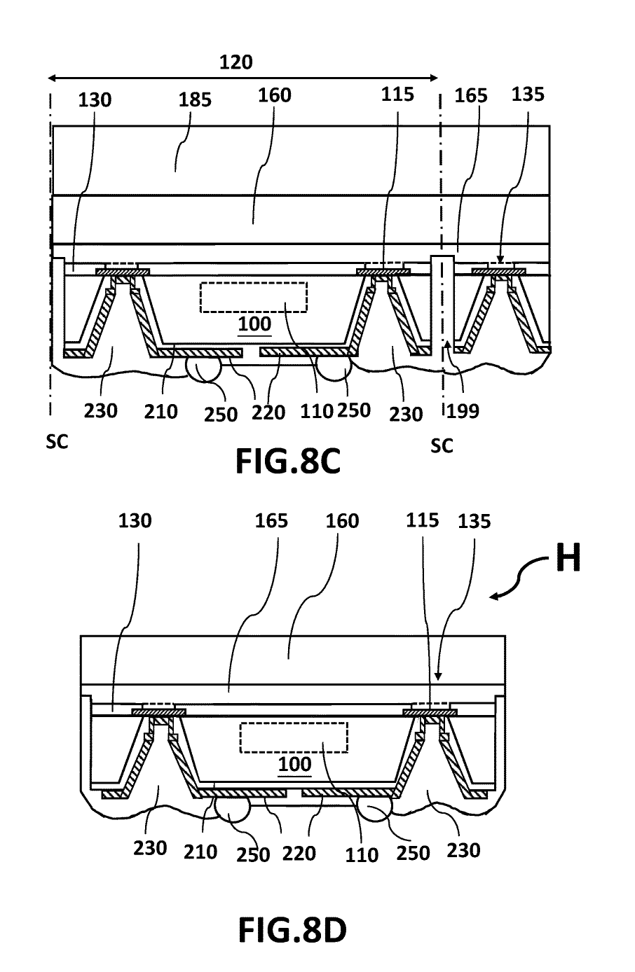

A detailed description of the chip scale sensing chip package and a method of manufacturing the same according to embodiment 8 of this invention is given below with reference to the accompany FIGS. 8A-8D.

First, please refer to FIG. 8A. A sensing device wafer 100 capped with a cap wafer 160 as shown in FIG. 1A is provided.

Next, please refer to FIG. 8B. A plurality of seventh through holes 197 exposing the conductive pads 115 are formed on the first bottom surface 100b of each chip area 120 by the same processes as shown in FIG. 7B. Then, a dielectric layer 210 us formed on the first bottom surface 100b of the sensing device wafer 100 and filled into the seventh through holes 197. Then, the dielectric layer 210 on the bottom of the seventh through holes 197 are removed to form a plurality of eighth through holes 198′ exposing the conductive pads 115, whereby each seventh through hole 197 interlinks with each eighth through hole 198′ and passes to each other.

Next, please refer to FIG. 8C. A patterned re-distribution layer 220 is formed on the dielectric layer 210. The patterned re-distribution layer 220 conformable extends onto the sidewalls (not shown) and the bottom walls (not shown) of the seventh through holes 197 and into the eighth through holes 198′ to electrically connect to the exposed conductive pads 115. Then, a structure as shown in FIG. 8C is generated after treating with the same processes as shown in FIG. 7D-7J.

Finally, please refer to FIG. 8D. The structure as shown in FIG. 8C is treated with the same processes as shown in FIG. 7K to generate a plurality of chip scale sensing chip packages H as shown in FIG. 8D.

### Exemplary Embodiment 9

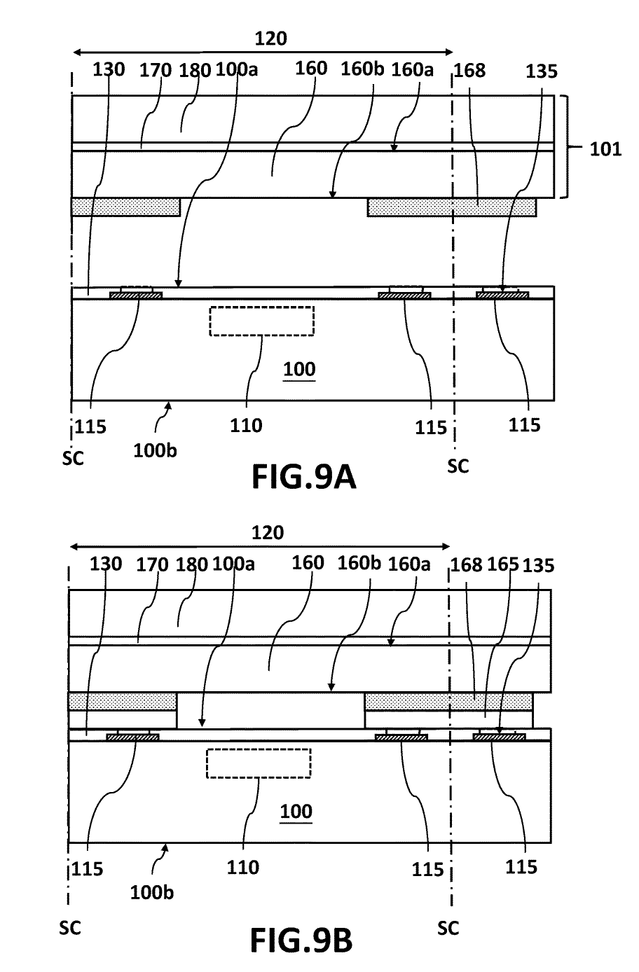

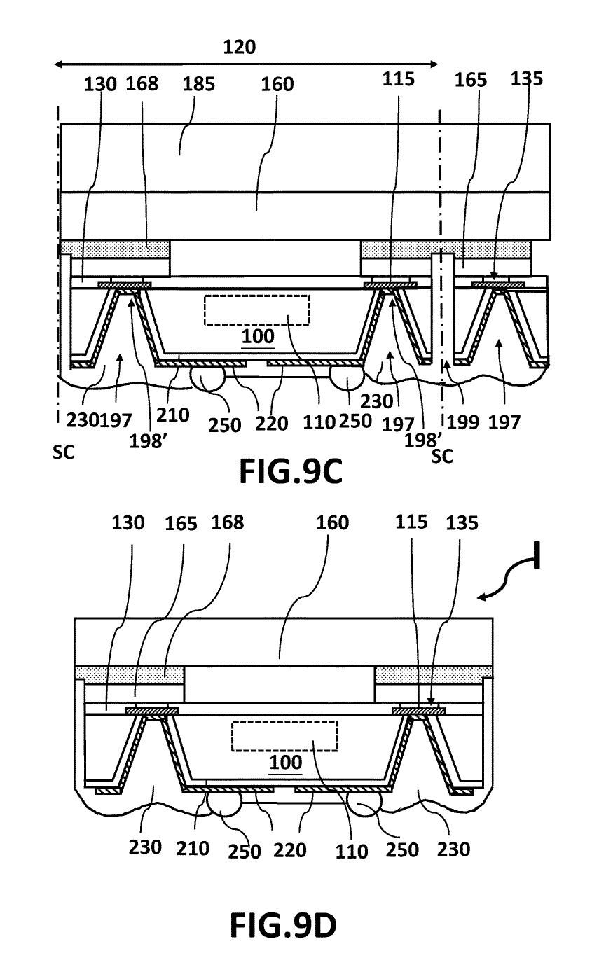

A detailed description of the chip scale sensing chip package and a method of manufacturing the same according to embodiment 9 of this invention is given below with reference to the accompany FIGS. 9A-9D.

First, please refer to FIG. 9A. A sensing device wafer 100 and a stacking layer 101 comprising a cap wafer 160, a second adhesive layer 170 and a temporary carrier substrate 180 as shown in FIG. 2A are provided. Then, a dam 168 is formed on the second bottom surface 160b of the cap wafer 160.

Next, please refer to FIG. 9B. A first adhesive layer 165 is coated on the dam 168 to make the stacking layer 101 bond to the first top surface 100a of the sensing device wafer 100.

Next, the structure as shown in FIG. 9B is treated with the same processes as shown in FIG. 7B-FIG. 7J to generate the structure as shown in FIG. 9C.

Finally, the structure as shown in FIG. 9C is treated with the same processes as shown in FIG. 7K to generate a plurality of chip scale sensing chip packages I as shown in FIG. 9D.

### Exemplary Embodiment 10

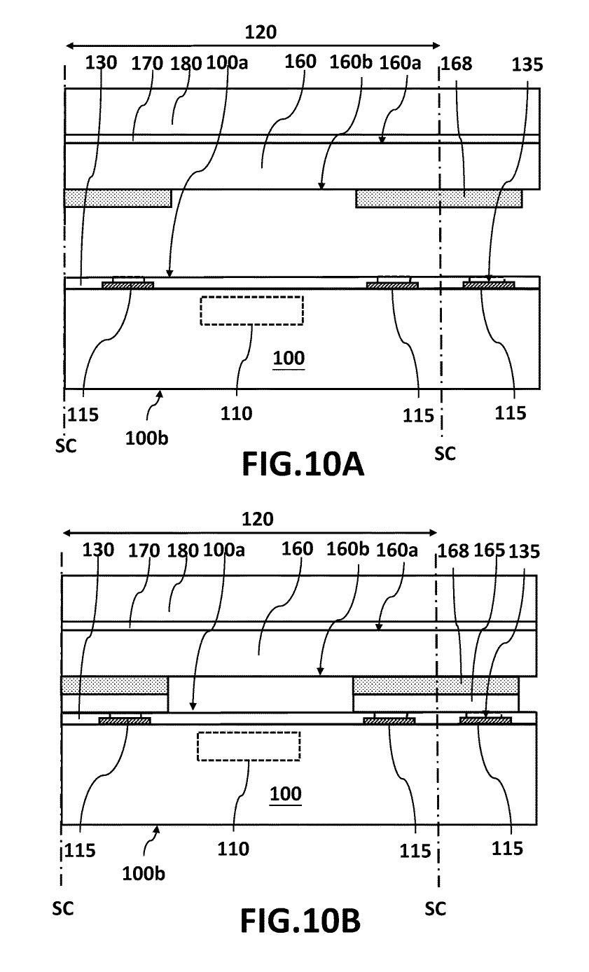

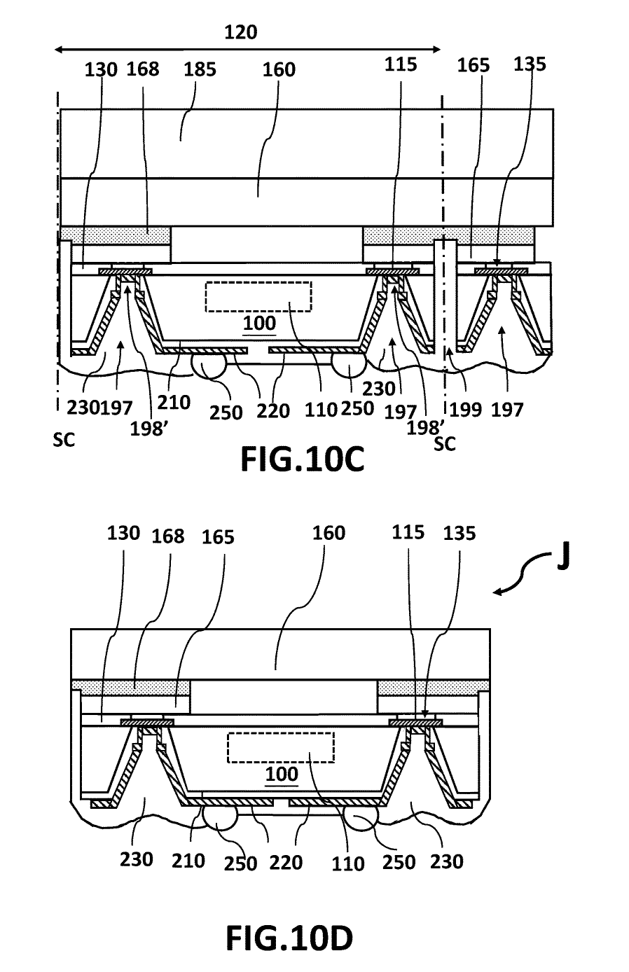

A detailed description of the chip scale sensing chip package and a method of manufacturing the same according to embodiment 10 of this invention is given below with reference to the accompany FIGS. 10A-10D.

First, please refer to FIG. 10A. A sensing device wafer 100 and a stacking layer 101 comprising a cap wafer 160, a second adhesive layer 170 and a temporary carrier substrate 180 as shown in FIG. 2A are provided. Then, a dam 168 is formed on the second bottom surface 160b of the cap wafer 160.

Next, please refer to FIG. 10B. A first adhesive layer 165 is coated on the dam 168 to make the stacking layer 101 bond to the first top surface 100a of the sensing device wafer 100.

Next, please refer to FIG. 10C. The structure as shown in FIG. 10B is treated with the same processes as shown in FIG. 8B-FIG. 8C to generate the structure as shown in FIG. 10C.

Finally, the structure as shown in FIG. 10C is treated with the same processes as shown in FIG. 7K to generate a plurality of chip scale sensing chip packages J as shown in FIG. 10D.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of manufacturing a chip scale sensing chip package, comprising the steps of:
providing a sensing device wafer having a first top surface and a first bottom surface opposite to each other, whereby the sensing device wafer comprises a plurality of chip areas, and each of the chip areas comprises a sensing device and a plurality of conductive pads adjacent to the sensing device nearby the first top surface;
providing a cap wafer having a second top surface and a second bottom surface opposite to each other, and bonding the second bottom surface of the cap wafer to the first top surface of the sensing device wafer by sandwiching a first adhesive layer therebetween;
providing a temporary carrier substrate, and bonding the temporary carrier substrate to the second top surface of the cap wafer by sandwiching a second adhesive layer therebetween;
forming a wiring layer connecting to each of the conductive pads on the first bottom surface of the sensing device wafer;
providing a first protective layer on the wiring layer;
removing the temporary carrier substrate and the second adhesive layer;
forming a second protective layer on the second top surface of the cap wafer;
removing the first protective layer;
scribing the chip areas to generate a plurality of individual chip scale sensing chip package; and
removing the second protective layer.

2. The method of manufacturing a chip scale sensing chip package as claimed in claim 1, whereby the method of manufacturing the wiring layer comprises the steps of:
thinning the first bottom surface of the sensing device wafer;
forming a plurality of first through holes on the thinned first bottom surface, wherein each of the first through holes exposes one of the conductive pads, and the cross-sectional area of each first through hole decreases with the distance from the thinned first bottom surface;
forming a dielectric layer overlaid the thinned first bottom surface and the first through holes and the conductive pads;
removing part of the dielectric layer on the bottom of each first through hole, part of conductive pads, part of the first top surface and part of the cap wafer to form a plurality of second through holes, whereby each of the second through holes has two side-walls respectively exposing one of the conductive pads;
forming a re-distribution layer on the dielectric layer, and electrically connecting to each conductive pad through each second through hole;
forming a passivation layer on the re-distribution layer, whereby the passivation layer has a plurality of third through holes exposing the re-distribution layer; and
forming a conductive structure in each of the third through holes and electrically connecting to the re-distribution layer.

3. The method of manufacturing a chip scale sensing chip package as claimed in claim 1, whereby the method of manufacturing the wiring layer comprises the steps of:
thinning the first bottom surface of the sensing device wafer;
forming a plurality of fourth through holes on the thinned first bottom surface, wherein each of the fourth through holes exposes one of the conductive pads;
forming a dielectric layer overlaid the thinned first bottom surface, the fourth through holes and the exposed conductive pads;
removing part or all of the dielectric layer on the bottom of each fourth through hole to form a plurality of fifth through holes exposing the conductive pads, whereby each of the fifth through holes interlinking with each of the fourth through holes;
forming a re-distribution layer on the dielectric layer, and electrically connecting to each conductive pad through each fifth through hole;
forming a passivation layer on the re-distribution layer, whereby the passivation layer has a plurality of sixth through holes exposing the re-distribution layer; and
forming a conductive structure in each of the sixth through holes and electrically connecting to the re-distribution layer.

4. The method of manufacturing a chip scale sensing chip package as claimed in claim 1, whereby the method of manufacturing the wiring layer comprises the steps of:
thinning the first bottom surface of the sensing device wafer;
forming a plurality of seventh through holes on the thinned first bottom surface, wherein each of the seventh through holes exposes one of the conductive pads;
forming a dielectric layer overlaid the thinned first bottom surface, the seventh through holes and the conductive pads;
removing part or all of the dielectric layer on the bottom of each seventh through hole to form a plurality of eighth through holes exposing the conductive pads, whereby each of the seventh through holes interlinking with each of the eighth through holes;
forming a re-distribution layer on the dielectric layer, and electrically connecting to each conductive pad through each eighth through hole;
removing part of the re-distribution layer, part of the dielectric layer, part of the sensing device wafer, part of the dielectric layer and part of the first adhesive layer nearby the boundary of two adjacent chip areas to form a trench;
forming a passivation layer on the re-distribution layer and extending into the trench, whereby the passivation layer has a plurality of ninth through holes exposing the re-distribution layer; and
forming a conductive structure in each ninth through holes and electrically connecting to the re-distribution layer.

5. The method of manufacturing a chip scale sensing chip package as claimed in claim 1, wherein the second protective layer is consisted of a material comprising a photo-sensitive glue.

6. The method of manufacturing a chip scale sensing chip package as claimed in claim 10, wherein the photo-sensitive glue is a UV glue.

7. The method of manufacturing a chip scale sensing chip package as claimed in claim 1, further comprising a step of cleaning the second top surface of the cap wafer before forming the second protective on the second top surface.

8. A method of manufacturing a chip scale sensing chip package, comprising the steps of:
providing a sensing device wafer having a first top surface and a first bottom surface opposite to each other, whereby the sensing device wafer comprises a plurality of chip areas, and each of the chip areas comprising a sensing device and a plurality of conductive pads adjacent to the sensing device nearby the first top surface;
providing a stacking layer comprising a cap wafer, a temporary carrier layer and a second adhesive layer sandwiched therebetween, whereby the cap wafer has a second top surface and a second bottom surface opposite to each other;
forming a dam on the second bottom surface of the cap wafer;
bonding the dam formed on the the stacking layer to the first top surface of the sensing device wafer by a first adhesive layer;
forming a wiring layer connecting to each of the conductive pads on the first bottom surface of the sensing device wafer;
providing a first protective layer on the wiring layer;
removing the temporary carrier substrate and the second adhesive layer;
forming a second protective layer on the second top surface of the cap wafer;
removing the first protective layer;
scribing the chip areas to generate a plurality of individual chip scale sensing chip package; and
removing the second protective layer.

9. The method of manufacturing a chip scale sensing chip package as claimed in claim 8, whereby the method of manufacturing the wiring layer comprises the steps of:
thinning the first bottom surface of the sensing device wafer;
forming a plurality of first through holes on the thinned first bottom surface, wherein each of the first through holes exposes one of the conductive pads, and the cross-sectional area of each first through hole decreases with the distance from the thinned first bottom surface;
forming a dielectric layer overlaid the thinned first bottom surface, the first through holes and the exposed conductive pads;
removing part of the dielectric layer on the bottom of each first through holes, part of conductive pads, part of the first top surface and part of the cap wafer to form a plurality of second through holes, whereby each of the second through holes has two side-walls respectively exposing one of the conductive pads;
forming a re-distribution layer on the dielectric layer, and electrically connecting to each conductive pad through each second through hole;
forming a passivation layer on the re-distribution layer, whereby the passivation layer has a plurality of third through holes exposing the re-distribution layer; and
forming a conductive structure in each third through holes and electrically connecting to the re-distribution layer.

10. The method of manufacturing a chip scale sensing chip package as claimed in claim 8, whereby the method of manufacturing the wiring layer comprises the steps of:
thinning the first bottom surface of the sensing device wafer;
forming a plurality of fourth through holes on the thinned first bottom surface, wherein each of the fourth through holes exposes one of the conductive pads;
forming a dielectric layer overlaid the thinned first bottom surface and the fourth through holes and the exposed conductive pads;
removing part or all of the dielectric layer on the bottom of each fourth through hole to form a plurality of fifth through holes exposing one of the conductive pads, whereby each of the fifth through holes interlinking with each of the fourth through holes;
forming a re-distribution layer on the dielectric layer, and electrically connecting to each conductive pad through each fifth through hole; and
forming a passivation layer on the re-distribution layer, whereby the passivation layer has a plurality of sixth through holes exposing the re-distribution layer;
forming a conductive structure in each sixth through holes and electrically connecting to the re-distribution layer.

11. The method of manufacturing a chip scale sensing chip package as claimed in claim 8, whereby the method of manufacturing the wiring layer comprises the steps of:
thinning the first bottom surface of the sensing device wafer;
forming a plurality of seventh through holes on the thinned first bottom surface, wherein each of the seventh through holes exposes one of the conductive pads;
forming a dielectric layer overlaid the thinned first bottom surface, the seventh through holes and the exposed conductive pads;
removing part or all of the dielectric layer on the bottom of each seventh through hole to form a plurality of eighth through holes exposing the conductive pads, whereby each of the eighth through holes interlinking with each of the seventh through holes;
forming a re-distribution layer on the dielectric layer, and electrically connecting to each conductive pad through each eighth through hole;
removing part of the re-distribution layer, part of the dielectric layer, part of the sensing device wafer, part of the dielectric layer and part of the first adhesive layer nearby the boundary of two adjacent chip areas to form a trench;
forming a passivation layer on the re-distribution layer and extending into the trench, whereby the passivation layer has a plurality of ninth through holes exposing the re-distribution layer; and
forming a conductive structure in each ninth through hole and electrically connecting to the re-distribution layer.

12. The method of manufacturing a chip scale sensing chip package as claimed in claim 8, wherein the second protective layer is consisted of a material comprising a photo-sensitive glue.

13. The method of manufacturing a chip scale sensing chip package as claimed in claim 12, wherein the photo-sensitive glue is a UV glue.

14. The method of manufacturing a chip scale sensing chip package as claimed in claim 8, further comprising a step of cleaning the second top surface of the cap wafer before forming the second protective layer on the second top surface.

15. A chip scale sensing chip package, comprising:
a chip scale sensing chip, having a first top surface and a first bottom surface opposite to each other, and a first sidewall and a second sidewall connecting to the opposite edges of the first top surface and the first bottom surface, whereby the surface area of the first top surface is greater than that of the first bottom surface, comprising:
a sensing device and a plurality of conductive pads nearby the sensing device adjacent to the first top surface, wherein the first sidewall and the second sidewall respectively expose one of the edge of the conductive pads;
a dielectric layer formed on the first bottom surface and the first, second sidewalls;
a re-distribution layer formed on the dielectric layer to respectively interconnect each conductive pad and each conductive structure;
a passivation layer overlaid the re-distribution layer, and the passivation layer having a plurality of third through holes exposing the re-distribution layer; and
a plurality of conductive structures electrically connecting to the re-distribution layer formed in the third through holes; and
a cap layer capped on the first top surface of the chip scale sensing chip, whereby the surface area of the cap layer is greater than that of the first top surface.

16. The chip scale sensing chip package as claimed in claim 15, further comprising a first adhesive layer sandwiched between the cap layer and the first top surface of the chip scale sensing chip.

17. The chip scale sensing chip package as claimed in claim 16, further comprising a dam sandwiched between the cap layer and the first adhesive layer.

18. The chip scale sensing chip package as claimed in claim 15, wherein the cap layer is consisted of a material selected from one of the group consisted of silicon, aluminum nitride, glass and ceramics, or combination thereof.

19. The chip scale sensing chip package as claimed in claim 18, wherein the first adhesive layer is selected from one of the group consisted of photoresist, polyimide (PI) and epoxy, or combination thereof.

20. A chip scale sensing chip package, comprising:
a chip scale sensing chip, having a first top surface and a first bottom surface opposite to each other, comprising:
a sensing device and a plurality of conductive pads nearby the sensing device adjacent to the first top surface;
a plurality of fourth through holes formed on the first bottom surface, whereby each fourth through hole has a bottom wall exposing one of the conductive pads and a sidewall surrounding the bottom wall;
a dielectric layer formed on the first bottom surface and the sidewall of each fourth through hole;
a re-distribution layer formed on the dielectric layer to electrically interconnect each conductive pad through the bottom wall of each fourth through hole;
a passivation layer formed on the re-distribution layer, and the passivation layer having a plurality of sixth through holes exposing the re-distribution layer; and
a plurality of conductive structures formed in the sixth through holes, and each conductive structure electrically connecting to the re-distribution layer; and
a cap layer capped on the first top surface of the chip scale sensing chip.

21. The chip scale sensing chip package as claimed in claim 20, further comprising a first adhesive layer sandwiched between the cap layer and the first top surface of the chip scale sensing chip.

22. The chip scale sensing chip package as claimed in claim 21, further comprising a dam sandwiched between the cap layer and the first adhesive layer.

23. The chip scale sensing chip package as claimed in claim 20, whereby the dielectric layer is formed on the first bottom surface, the bottom wall and the sidewall of each fourth through hole of the chip scale sensing chip, and the bottom wall further comprises a fifth through hole exposing one of the conductive pads, and the re-distribution layer electrically connects to each conductive pad through each fifth through hole.

24. A chip scale sensing chip package, comprising:
a chip scale sensing chip, having a first top surface and a first bottom surface opposite to each other, comprising:
a sensing device and a plurality of conductive pads nearby the sensing device adjacent to the first top surface;
a plurality of seventh through holes formed on the first bottom surface, and each seventh through hole having a bottom wall exposing one of the conductive pads and a sidewall surrounding the bottom wall;
a trench surrounding the outer of each seventh through hole formed on the first bottom surface;
a dielectric layer formed on the first bottom surface and the sidewall of each seventh through hole;
a re-distribution layer formed on the dielectric layer to electrically connect each conductive pad through the bottom wall of each fourth through hole;
a passivation layer overlay the re-distribution layer and gap-filled into the trench, whereby the passivation layer has a plurality of ninth through holes exposing the re-distribution layer; and
a plurality of conductive structures formed in the ninth through holes, and each conductive structure electrically connecting to the re-distribution layer; and
a cap layer capped on the first top surface of the chip scale sensing chip.

25. The chip scale sensing chip package as claimed in claim 24, further comprising a first adhesive layer sandwiched between the cap layer and the first top surface of the chip scale sensing chip.

26. The chip scale sensing chip package as claimed in claim 25, further comprising a dam sandwiched between the cap layer and the first adhesive layer.

27. The chip scale sensing chip package as claimed in claim 24, whereby the dielectric layer is formed on the first bottom surface, the bottom wall and the sidewall of each seventh through hole of the chip scale sensing chip, and the bottom wall further comprises a eighth through hole exposing one of the conductive pads, and the re-distribution layer electrically connects to each conductive pad through each eighth through hole.
